(19) United States
(12) Patent Application Publication
(10) Pub. No.: US 2019/0082151 A1
(43) Pub. Date: Mar. 14, 2019

(54) PROJECTOR

(71) Applicant: HON HAI PRECISION INDUSTRY CO., LTD., New Taipei (TW)

(72) Inventor: KATSUHIKO KISHIMOTO, Osaka (JP)

(73) Assignee: Hon Hai Precision Industry Co., Ltd., New Taipei (TW)

(21) Appl. No.: 16/079,552

(22) PCT Filed: Jul. 21, 2016
(86) PCT No.: PCT/JP2016/071364

§ 371 Date: Aug. 23, 2018

(30) Foreign Application Priority Data
Feb. 24, 2016 (JP) 2016-032991

(51) Int. Cl. H04N 9/31; G03B 21/20; H04N 5/74; H01S 5/022

(52) U.S. Cl. CPC H04N 9/3161; G03B 21/2033; H04N 9/3105; H04N 5/7416; H01S 5/022; G03B 21/2013

(57) ABSTRACT

A projector projects an image on an object in a focus-free manner. The projector includes a transmissive spatial light modulator (20) that forms a two-dimensional pattern for defining the image; and a laser light source (10) that irradiates the spatial light modulator (20) with laser light (30). The spatial light modulator (20) generates a bundle of a plurality of light beams (300), having a spatial intensity distribution of the two-dimensional pattern, from the laser light (30).

### TECHNICAL FIELD

The present disclosure relates to a projector for projecting an image on an object, and specifically to a focus-free projector not requiring focus adjustment to be performed in accordance with the distance to the object on which the image is to be projected.

### BACKGROUND ART

A known projector is a device that projects a still image or a moving image on a flat plane such as a screen or the like to display the image. The image to be projected (primary image) is, for example, a still image on a photographic slide (positive film) or a still/moving image on a liquid crystal panel. The photographic slide or the liquid crystal panel is a display medium that forms a two-dimensional pattern defining an image, and is irradiated by use of a light source such as a high-intensity discharge lamp or an LED (Light Emitting Diode) to form the two-dimensional pattern (luminance distribution). The primary image is projected on a screen, which is a display plane, by a projection lens optical system, and an expanded image is formed. Typical examples of such a projector include a data projector, a video projector, a game projector, a front projection TV set, a rear projection TV set, and the like.

A conventional projector is not able to form an focused image on the screen unless the focal distance of the projection lens optical system is adjusted each time the distance of the projector to the screen (projection distance) is changed or the display magnification is changed. This will be described below with respect to FIG. 7.

In order to solve such a problem, a focus-free projector, which scans the screen with a narrow collimated laser beam at a high speed, has been proposed (e.g., Patent Document 1). Such a projector performs raster scan with a laser beam by use of an MEMS (Micro Electro Mechanical System) mirror while modulating the intensity of the laser beam in accordance with luminance signals, and thus forms an image. The size of an irradiation spot, on the screen, irradiated with the laser beam does not vary almost at all in accordance with the projection distance. Therefore, a clear image is formed with no focusing.

### CITATION LIST

### Patent Literature

Patent Document No. 1: Japanese Laid-Open Patent Publication No. 2011-221060

### SUMMARY OF INVENTION

### Technical Problem

The projector described in Patent Document 1 outputs one or several narrow collimated laser beams having a high optical intensity (power density) from a laser light source. Therefore, if such a laser beam inadvertently enters the eye of a viewer, a problem of retina damage or the like may occur. For this reason, it is necessary to provide a regulation such that a human cannot enter an area between the projector and the screen, or to decrease the intensity of the laser beam to a level at which if the laser light enters the eye, no adverse effect is exerted. This decreases the degree of designing freedom of the projector system and prevents realization of a bright display image.

Embodiments of the present disclosure provide projectors each having a completely novel structure to operate in a focus-free manner.

### Solution to Problem

A projector according to the present invention is, in an illustrative embodiment, is a projector for projecting an image on an object in a focus-free manner. The projector includes a transmissive spatial light modulator that forms a two-dimensional pattern for defining the image; and a laser light source that irradiates the spatial light modulator with laser light. The spatial light modulator generates a bundle of a plurality of light beams, having a spatial intensity distribution of the two-dimensional pattern, from the laser light.

A projector according to the present invention is, in another embodiment, a projector for projecting an image on an object in a focus-free manner. The projector includes a plurality of transmissive spatial light modulators each forming a two-dimensional pattern for defining the image; and a plurality of laser light sources that respectively irradiate the plurality of spatial light modulators with laser light in different wavelength ranges. The plurality of spatial light modulators each generate a bundle of a plurality of light beams, having a spatial intensity distribution of the two-dimensional pattern, from the laser light.

A projector according to the present invention is, in still another embodiment, is a projector for projecting an image on an object in a focus-free manner. The projector includes a spatial light modulator that forms, on a light modulation region, a two-dimensional pattern for defining the image; and one or a plurality of semiconductor laser devices that irradiate the light modulation region of the spatial light modulator with laser light. The spatial light modulator generates a bundle of a plurality of light beams, having a spatial intensity distribution of the two-dimensional pattern, from the laser light; and the one or the plurality of semiconductor laser devices are all located such that a semiconductor layer-layer-stacking direction thereof is perpendicular to a minimum size direction of the light modulation region of the spatial light modulator.

### Advantageous Effects of Invention

In embodiments according to the present disclosure, a bundle of a plurality of light beams output from a transmissive spatial light modulator is incident on an object, and an image including, as pixels, irradiation points at which the object is irradiated with the light beams is formed on the object. The light beams formed of laser light have a high directivity, and therefore, a clear image is projected on the object regardless of the distance from the projector to the object.

### BRIEF DESCRIPTION OF DRAWINGS

FIG. 1 is a cross-sectional view schematically showing a non-limiting illustrative example of structure of a projector according to the present disclosure.

FIG. 2 is a front view schematically showing an example of structure of a spatial light modulator 20 usable for the projector according to the present disclosure.

FIG. 3A is a cross-sectional view schematically showing light beams 300a and 300b output from two openings (pixel regions) 22 of the spatial light modulator 20 forming a certain two-dimensional pattern.

FIG. 3B is a cross-sectional view schematically showing light beams 300a, 300b, 300C and 300d output from four openings (pixel regions) 22 of the spatial light modulator 20 forming another two-dimensional pattern.

FIG. 3C is a cross-sectional view showing an example in which laser light 30 is incident on the spatial light modulator 20 obliquely.

FIG. 4 is a cross-sectional view schematically showing an example in which the light beams 300a and 300b output from the openings (pixel regions) 22 of the spatial light modulator 20 diverge by diffraction.

FIG. 5 is a cross-sectional view showing a microlens array-including spatial light modulator 20 including microlenses provided on the output side of the openings (pixel regions) 22.

FIG. 6 shows an example of structure in which the laser light 30 emitted from a laser light source 10 is incident on the spatial light modulator 20 without being collimated.

FIG. 7 shows an example of structure of a conventional projector using a projection lens optical system.

FIG. 8A is an isometric view schematically showing an example in which text data is projected and displayed on a screen 200 by use of a projector 100 according to the present disclosure.

FIG. 8B is an isometric view showing a state where a part of light beams output from the projector 100 is blocked by another screen 200a.

FIG. 8C is an isometric view schematically showing a state where the screen 200 is inclined.

FIG. 8D is an isometric view showing an example in which an image is displayed on a screen 200 that is not flat but is folded in the middle.

FIG. 9 is a cross-sectional view schematically showing an example of structure of the projector 100 in an embodiment according to the present disclosure.

FIG. 10 is a cross-sectional view schematically showing an example of structure of the spatial light modulator 20 in an embodiment according to the present disclosure.

FIG. 11 is a cross-sectional view showing an example of structure of a projector 100 in another embodiment according to the present disclosure.

FIG. 12 is a cross-sectional view showing an example of structure of a projector 100 in still another embodiment according to the present disclosure.

FIG. 13 is a cross-sectional view showing an example of structure of a projector 100 in still another embodiment according to the present disclosure.

FIG. 14 is a cross-sectional view showing an example of structure of a projector 100 in still another embodiment according to the present disclosure.

FIG. 15 is a cross-sectional view showing an example of structure of a projector 100 in still another embodiment according to the present disclosure.

FIG. 16 is a cross-sectional view showing an example of structure of a projector 100 in still another embodiment according to the present disclosure.

FIG. 17 is a cross-sectional view showing an example of structure of a projector 100 in still another embodiment according to the present disclosure.

FIG. 18A is a view showing an operation of the projector 100 of projecting a color image by a field sequential method.

FIG. 18B is another view showing an operation of the projector 100 of projecting a color image by the field sequential method.

FIG. 18C is still another view showing an operation of the projector 100 of projecting a color image by the field sequential method.

FIG. 19 shows a time-wise change in lit-up states of laser light sources 10R, 10G and 10B in the projector 100 operating by the field sequential method.

FIG. 20 shows an example of structure of a three-panel projector 100 according to the present disclosure.

FIG. 21 is an isometric view schematically showing a basic structure of a typical semiconductor laser device.

FIG. 22A is an isometric view schematically showing spreading (divergence) of the laser light 30 emitted from a light emission region 124 of a semiconductor laser device 10D.

FIG. 22B is a side view schematically showing the divergence of the laser light 30, FIG. 22B also showing, in a right part thereof, a front view of the semiconductor laser device 10D as seen in a positive direction along a z-axis direction, for reference.

FIG. 22C is a plan view schematically showing the divergence of the laser light 30.

FIG. 22D is a graph showing the divergence of the laser light 30 in a y-axis (fast-axis) direction.

FIG. 22E is a graph showing the divergence of the laser light 30 in an x-axis (slow-axis) direction.

FIG. 23 is a graph showing the relationship between the distance of the cross-section from the light emission region 124 (position in the z-axis direction) and each of size Ey in the y-axis direction and size Ex in the x-axis direction of a cross-section of the laser light 30.

FIG. 24 is an isometric view showing an example of structure provided to realize the projector 100 shown in FIG. 15 using the semiconductor laser device 10D.

FIG. 25 is an isometric view showing another example of structure provided to realize the projector 100 shown in FIG. 15 using the semiconductor laser device 10D.

FIG. 26 shows an example of structure of an exposure device projecting an image on a work 200b having a stepped portion at a surface thereof.

FIG. 27 shows an example of structure in which a bundle of light beams 300 is incident on a light receiving surface of a photo-receiving device 200c such as an image sensor or the like.

### DESCRIPTION OF EMBODIMENTS

### Terms

The “object” encompasses a wide variety of items including a screen, a wall, a glass item, a desktop, a building, a road, a vehicle, a part of a body of a creature (e.g., arm, palm, back, etc.) or the entirety of such a body, water drop or an assembly of powdery particles, a fluid, a semitransparent item, a photosensitive resin, an image sensor (photo-receiving device), and the like.

The “image” is not limited to a character, a symbol, a picture or the like, and encompasses a random pattern having no meaning, an encoded pattern such as a two-dimensional barcode or the like, a pattern of a circuit wiring, and the like.

The “projection” encompasses enlargement and also shrinkage.

The “laser light” is not limited to laser light generated by single mode oscillation, and encompasses laser light generated by multiple mode oscillation, and also light generated by multiplexing of laser light components having different wavelengths. The laser light is not limited to visible light, and may be infrared or ultraviolet waves (electromagnetic waves).

The “spatial light modulator” is a device that spatially modulates light intensity (amplitude of electromagnetic waves), and does not encompass a device that spatially modulates only a phase of the waves. A typical example of the spatial light modulator is a liquid crystal panel (transmissive liquid crystal display device) capable of changing light transmittance in units of pixels. The spatial light modulator may be a photographic slide (positive film or reversal film), a specimen on a glass plate for observation, an OHP sheet or a silhouette artwork usable for shadow play that forms a two-dimensional pattern not changed timewise. Such a display medium may be optionally replaced with another display medium to change the two-dimensional pattern. The spatial light modulator may be expressed simply as the “SLM”.

<Principle>

Before specifically describing embodiments of a projector according to the present disclosure, an example of basic structure and the principle of operation of the projector will be described.

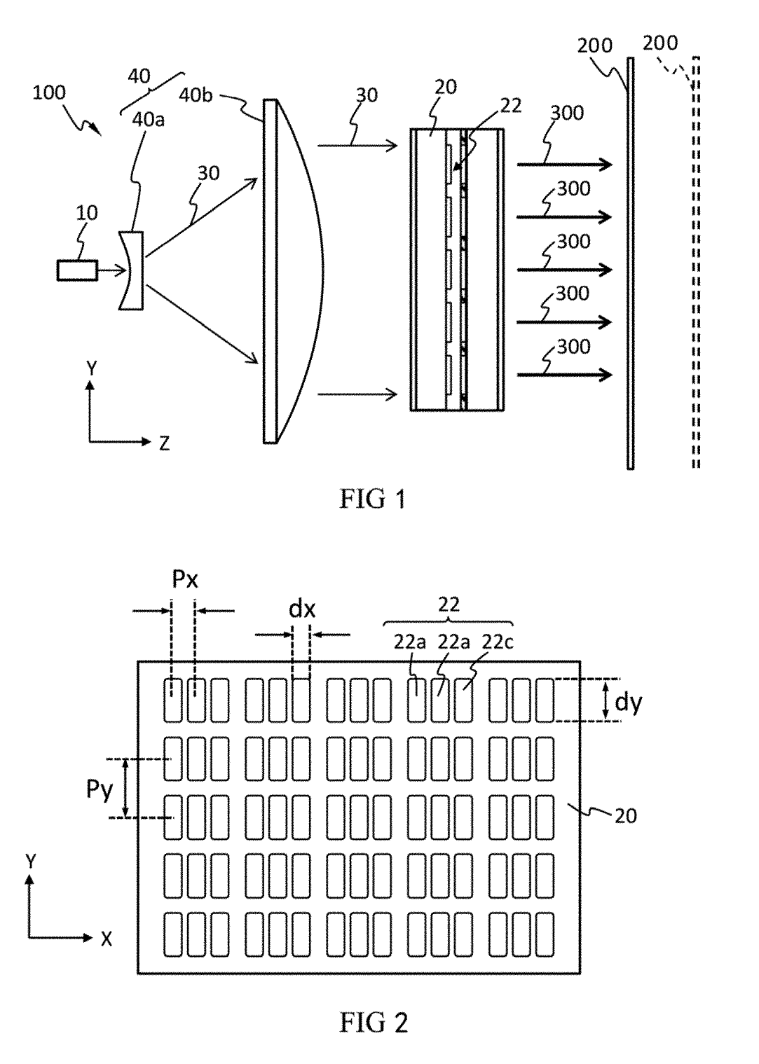

FIG. 1 is a cross-sectional view showing an illustrative example of basic structure of a projector 100 according to the present disclosure. In the figure, coordinate axes (Y axis and Z axis) associated with directions regarding the projector are shown. Although not shown in FIG. 1, an X axis is perpendicular to both of the Y axis and the Z axis. An XYZ coordinate system is formed of the X axis, the Y axis and the Z axis perpendicular to each other. In the other figures, the coordinate axes may be shown when necessary.

The projector 100 projects an image on an object such as a screen 200 or the like, and includes a transmissive spatial light modulator 20 that forms a two-dimensional pattern for defining an image, and a laser light source 10 that irradiates the spatial light modulator 20 with laser light 30. FIG. 1 shows a structure in which the laser light 30 has an optical axis parallel to the Z axis, for the sake of simplicity. The direction of the optical axis of the laser light 30 may be changed in the middle of propagation by a mirror (not shown) located on an optical path.

In this example, the laser light 30 emitted from the laser light source 10 is shaped by a beam shaping lens 40. In this example, the beam shaping lens 40 includes a concaved lens 40a and a convexed lens 40b. The size (diameter) of a cross-section of the laser light 30 perpendicular to the optical axis thereof is enlarged by the concaved lens 40a and collimated by the convexed lens 40b, so that the laser light 30 becomes parallel light. The laser light 30 transmitted through the beam shaping lens 40 irradiates a rear surface of the spatial light modulator 20. The laser light 30 is transmitted through a plurality of openings 22 included in the spatial light modulator 20 and is output as a bundle of light beams 300. The plurality of light beams 300 each have an intensity thereof modulated when being transmitted through the corresponding opening 22 of the spatial light modulator 22.

FIG. 2 is a front view schematically showing an example of positional arrangement of the openings 22 in the spatial light modulator 20 usable for the projector 100 according to the present disclosure. The spatial light modulator 20 generates the bundle of the plurality of light beams 300, having a two-dimensional spatial intensity distribution along an XY plane, of the laser light 30 (see FIG. 1). Specifically, an array of the openings 22 respectively transmitting the plurality of light beams 300 is formed, and one light beam 300 is output from each of the openings 22. A region other than the openings 22 does not need to be covered with one continuous light blocking layer. As long as, for example, a plurality of metal interconnect lines extending in the X-axis direction and a plurality of metal interconnect lines extending in the Y-axis direction cross each other and a region that transmits light is divided into a plurality of regions as seen in the Z-axis direction, each of the plurality of regions acts as the “opening”.

The positional arrangement of the openings 22 shown in FIG. 2 is merely an example, and the positional arrangement is not limited to the pattern in the example shown in FIG. 2. A delta arrangement in which each of the openings 22 is located at an apex of a triangle may be adopted. The individual openings 22 are not limited to being rectangular, and may be square, hexagonal, polygonal, circular, elliptical or of any other complicated shape. The openings 22 do not need to be arranged regularly, and may be arranged irregularly.

Regarding the example of positional arrangement shown in FIG. 2, the size of one opening 22 in the X-axis direction is labeled dx, and the size of one opening 22 in the Y-axis direction is labeled dy. In this case, dx and dy may each be set to be in the range of, for example, about 1 μm to about 100 μm. The distance between the centers of the openings 22 in the X-axis direction is labeled Px, and the distance between the centers of the openings 22 in the Y-axis direction is labeled Py. In this case, Px and Py may respectively be set to, for example, about 1.1 times to about twice the sizes dx and dy.

In the example shown in FIG. 2, the openings 22 are shown in the number of 15×5 (horizontal×vertical). This is merely an example, and the number of the openings 22 formed in one spatial light modulator 20 may be, for example, 1024 (horizontal)×768 (vertical). The number of the openings 22 may be larger than, or smaller than, this number, and may be set to any value in accordance with the number of pixels required to be included in the projected image.

In the spatial light modulator 20 in this example, the light transmittance of each of the openings 22 may be changed in an analog manner in response to a driving signal (video signal), and thus the intensity of each of the light beams 300 is adjusted. It is assumed that, for example, openings 22a, 22b and 22c are respectively set to have transmittances of 100%, 60% and 0%. In this case, where the intensity of the light beam 300 output from the opening 22a (square of the electric field amplitude) is 100 (arbitrary unit), the intensity of the light beam 300 output from the opening 22b (square of the electric field amplitude) is 60. The light beam 300 is not output from the opening 22c. The spatial transmittance distribution of the spatial light modulator 20 may be adjusted in this manner, so that the spatial intensity distribution of the bundle of the light beams 300 output from such a large number of openings 22 is controlled. A typical example of the spatial light modulator 20 having such a function is a transmissive liquid crystal panel. In the case where the spatial light modulator 20 is realized by a transmissive liquid crystal panel, a plurality of pixel regions of the liquid crystal panel may act as the plurality of openings 22. An example of structure and an operation of the liquid crystal panel will be described below.

The spatial light modulator 20 according to the present disclosure modulates the “amplitude (intensity)”, not the “phase”, of the incident laser light 30 in units of pixels. The angle at which the light beam 300 is output from each opening 22 of the spatial light modulator 20 is constant for each opening 22, regardless of the two-dimensional pattern (planar distribution of the transmittance) to be formed.

As shown in FIG. 1, the bundle of the light beams 300 output from the spatial light modulator 20 is incident on the screen 200 and forms an array of irradiation points (light beam spots) on the screen 200. As a result, an image including, as pixels, the irradiation points of the light beams 300 on the screen 200 is formed on the screen 200. Such an array of the irradiation points of the light beams 300 forms a projected image in accordance with the two-dimensional pattern on the spatial light modulator 20. The plurality of light beams 300 output from the spatial light modulator 20 are formed of the laser light 30 having a high spatial coherence, and thus each light beam 300 has a high directivity. Therefore, even if the distance from the spatial light modulator 20 to the screen 200 is changed, for example, even if the screen 200 is moved to the position represented by the dashed line, “blur due to defocusing” does not occur to the projected image, and the clarity of the image is not changed.

As described above, the projector according to the present disclosure operates in a focus-free manner, and forms a clear image with no “blur due to defocusing” at any projection distance.

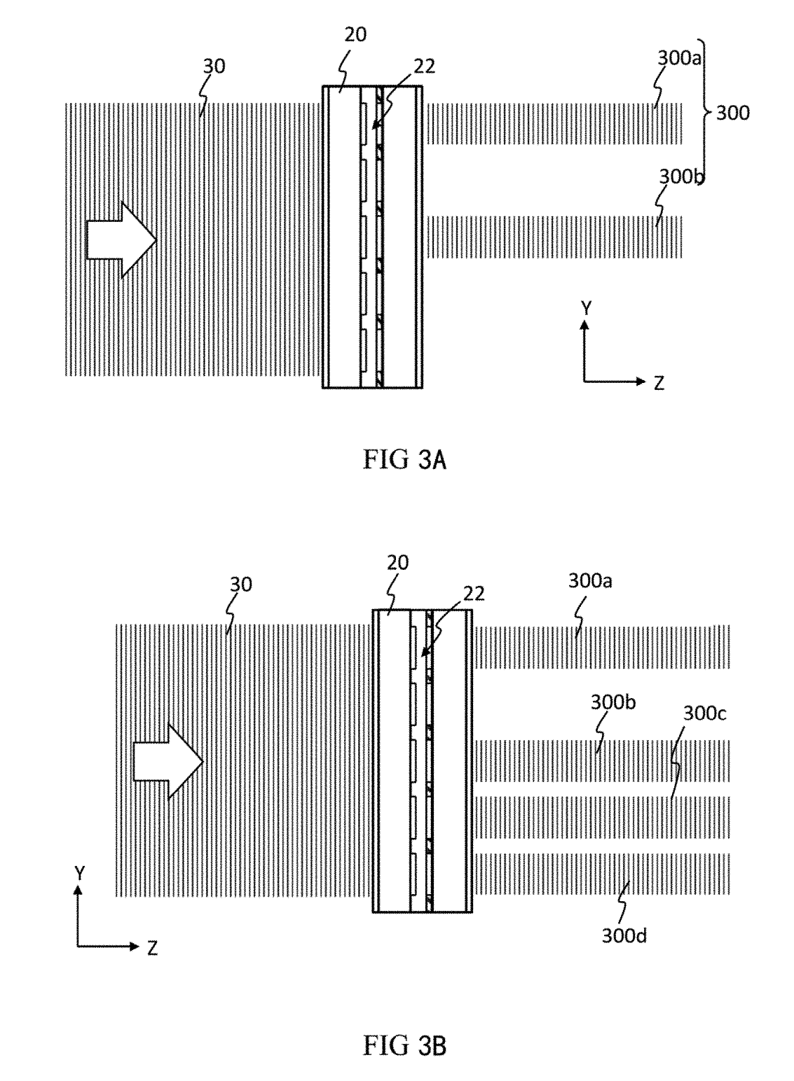

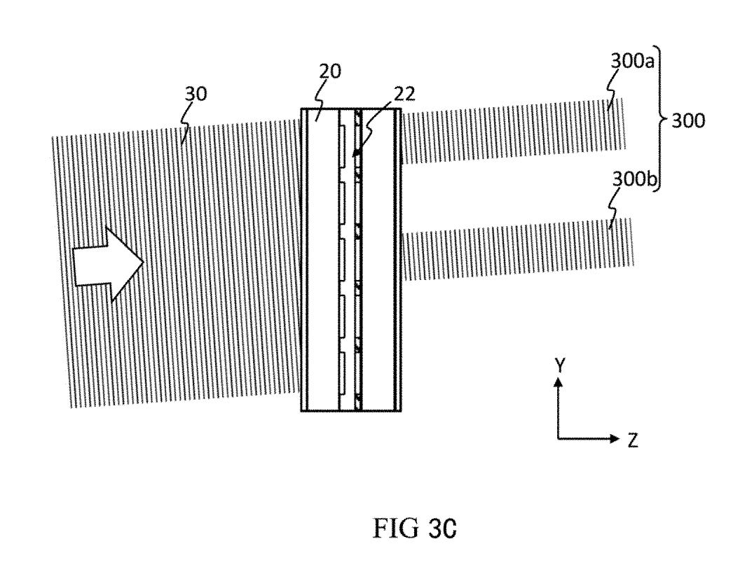

FIG. 3A is a cross-sectional view schematically showing the laser light 30 incident on the spatial light modulator 20 forming a certain two-dimensional pattern, and also schematically showing light beams 300a and 300b output from two openings 22 of the spatial light modulator 20. The openings 22 from which no light beam 300 is output is set to have a transmittance of 0%. The laser light 30 is a light wave having a high coherence, and in the example shown in the figure, is a planar monochromatic wave (single wavelength).

FIG. 3B is a cross-sectional view schematically showing the laser light 30 incident on the spatial light modulator 20 forming another two-dimensional pattern, and also schematically showing light beams 300a, 300b, 300c and 300d output from four openings 22 of the spatial light modulator 20. The openings 22 from which no light beam 300 is output is set to have a transmittance of 0%.

As shown in FIG. 3A and FIG. 3B, the bundle of the light beams 300 output from the spatial light modulator 20 has a spatial intensity distribution in accordance with the two-dimensional pattern formed by the spatial light modulator 20. In the case where an object is located to block a part of, or the entirety of, the bundle of the light beams 300, the light beams 300 incident on the object form bright light beam spots on a surface of the object. An array of these light beam spots (luminance points) acts as a pixel array to form a projected image. Therefore, no projection lens optical system is needed in order to form an image. The bundle of the light beams 300 output from the spatial light modulator 20 may be referred to as an “array of needle beams”.

FIG. 3C is a cross-sectional view showing an example in which the laser light 30 is incident on the spatial light modulator 20 obliquely. In the example shown in the figure, the light beams 300a and 300b are output obliquely. As can be seen, the laser light 30 may be incident on the spatial light modulator 20 obliquely, instead of perpendicularly. The laser light 30 does not need to be a planar wave, and may a spherical wave as long as the wavefront thereof has a radius of curvature sufficiently greater than the size of the openings 22. The wavelength of the laser light 30 is not limited to one, and different wavelengths of laser light 30 may be incident on one, same the spatial light modulator 20 at the same time or sequentially. In the case where the projected image is not to be viewed by a human, the wavelength of the laser light 30 may be outside of a visible light range.

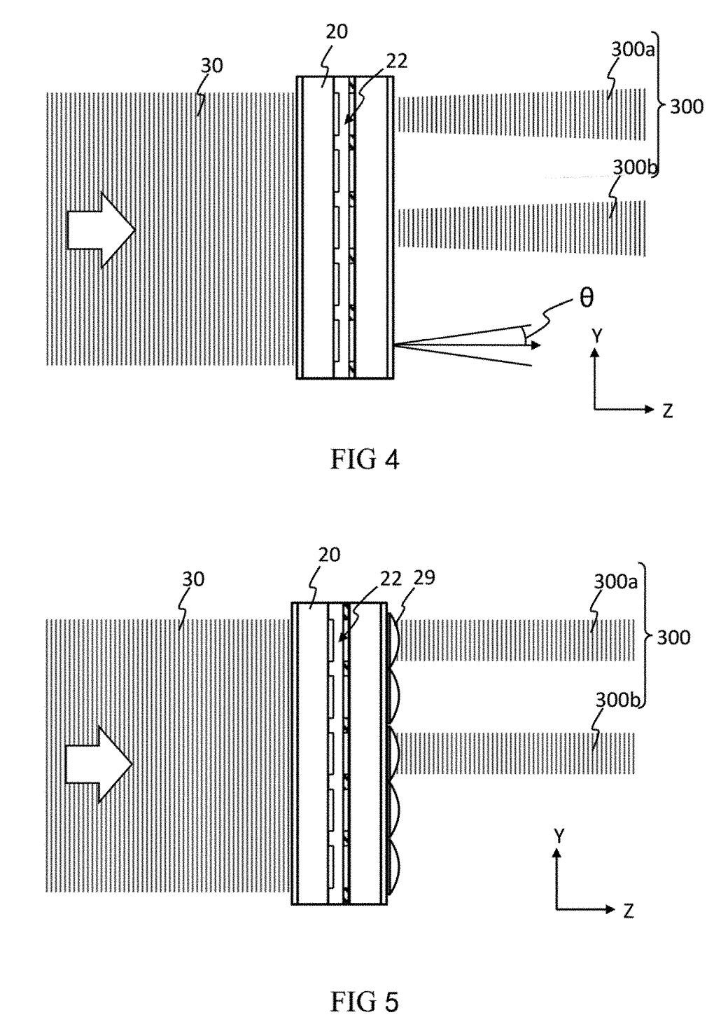

FIG. 4 shows an example in which the light beams 300a and 300b output from the openings 22 of the spatial light modulator 20 diverge by an effect of diffraction caused by the openings 22. The diffraction of the light beams 300 is, on principle, regulated by the shape and the size of the individual openings 22 and the wavelength λ of the laser light 30. In general, as the size of the openings 22 is smaller, the diffraction is stronger and the light beams 300 diverge more easily. The divergence of an individual light beam 300 may be defined by how much the size of a cross-section of the light beam 300 perpendicular to the optical axis (Z axis) thereof increases in accordance with the increase in the value of the Z coordinate. Where the distance from a light output surface of the spatial light modulator 20 to the light beam 300 is Rz and the diameter of the cross-section of the light beam 300 at the distance Rz is D(Rz), there is approximately the relationship of D(Rz)=2θ ×Rz. In the case where a screen is located at the position of the distance Rz, the size of the light beam spot (pixel) on the screen is equal to D(Rz).

Such divergence of the light beams 300 by diffraction is ignorable in the case where the size of the openings 22 is sufficiently greater than the wavelength λ of the laser light 30 and the projection distance is short. However, in the case where the size of the openings 22 is small and the projection distance is long, it is preferred that as shown in, for example, FIG. 5, a microlens array 29 is located on the output side of the openings 22 in order to suppress the divergence of the light beams 300. Microlenses included in the microlens array 29 adjust wavefronts of the light beams 300 output from the corresponding openings 22 such that the divergence of the light beams 300 caused by the diffraction is counteracted, and thus collimate the light beams 300. The control, by the microlens array 29, on the divergence of the light beams 300 is only realized by adopting the transmissive spatial light modulator 20.

The component usable to suppress the light beams 300 from diverging by the diffraction caused by the openings 22 is not limited to the microlens array 29. In the case where a liquid crystal panel is used as the spatial light modulator 20, the electric fields distribution formed in the vicinity of each of pixel electrodes may be adjusted to appropriately control the refractive index distribution in a liquid crystal layer, so that a lens effect is provided to counteract the effect of diffraction.

The diffraction may be caused also by the large number of openings 22 being arrayed periodically. The diffraction caused by such a “multi-slit” may be convoluted by the diffraction caused by a “single slit” of each opening 22 and as a result, may generate a narrow, squeezed light beam at a center of each opening 22. In this case, even without the microlens array 29, sufficiently narrow light beams 300 are realized for a long distance.

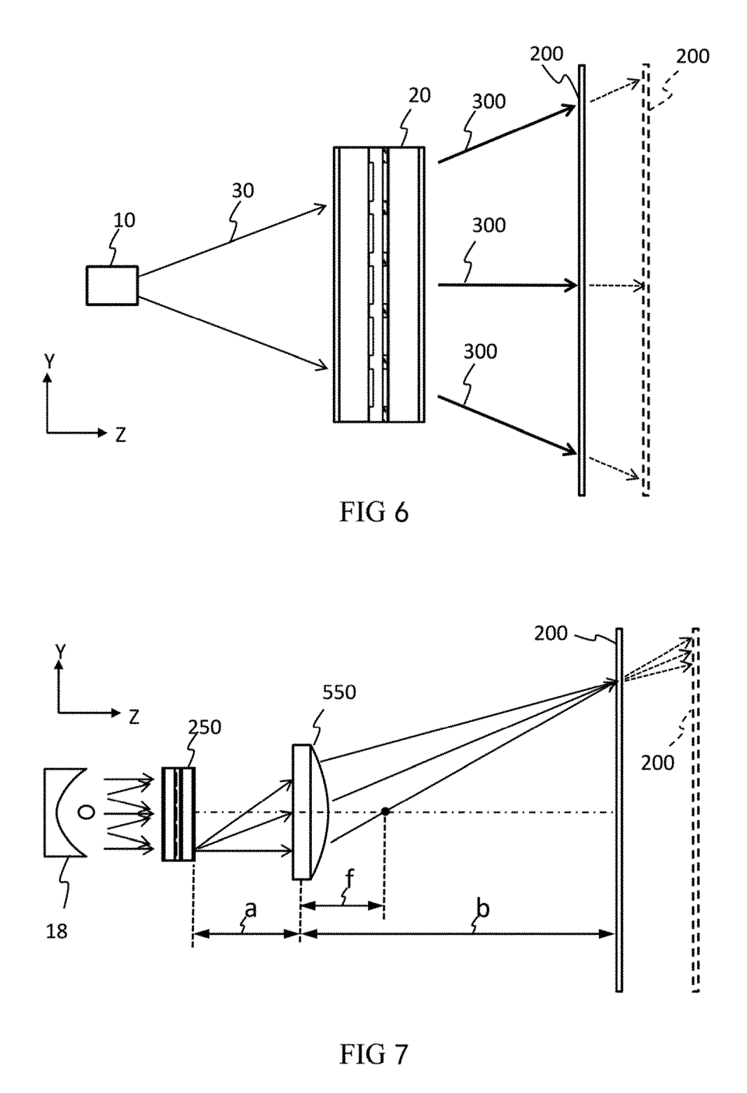

FIG. 6 shows an example of structure in which the laser light 30 emitted from the laser light source 10 is incident on the spatial light modulator 20 without being collimated into parallel light. In this example, the laser light 30 emitted from the laser light source 10 is incident on the spatial light modulator 20 while expanding a cross-section thereof perpendicular to the optical axis thereof. In other words, the laser light 30 having a curved wavefront like a spherical wave is incident on the spatial light modulator 20. However, from the point of view of each of the openings 22, such laser light 30 may be approximately considered as a planar wave incident thereon at a predetermined angle because the size of the openings 22 is sufficiently smaller/shorter than the radius of curvature of the wavefront. The plurality of light beams 300 formed of such laser light 30 are not parallel to each other, but have output angles in accordance with the positions of the corresponding openings 22. Therefore, in the case where no optical element such as a lens or the like is provided between the spatial light modulator 20 and the screen 200, when the distance from the spatial light modulator 20 to the screen 200 is changed, the size of the image formed on the screen 200 is also changed. In the example shown in FIG. 6, as the distance from the spatial light modulator 20 to the screen 200 is made longer, the image formed on the screen 200 is made larger. The “size of the image” is in proportion to the interval between the light beam spots on the screen 200 (distance between the centers of the light beam spots). Even when the image is made larger, the number of the light beam spots (pixels) forming the image is not changed. Even in this case, focusing is not needed, and an image with no “blur due to defocusing” is formed on the screen 200 located at an arbitrary position.

Now, with reference to FIG. 7, an example of image formation by a conventional projector using a projection lens optical system will be described. The projector shown in FIG. 7 includes an incoherent light source 18 such as a xenon lamp or the like that emits white light, a liquid crystal panel 250, and a projection lens optical system 550. Where the distance from a surface (object surface) of the liquid crystal panel 250 displaying a primary image to the projection lens optical system 550 is a, the distance from the projection lens optical system 550 to the screen 200 (projection distance) is b, and the focal distance of the projection lens optical system 550 is f, there needs to be the relationship of 1/a×1/b=1/f. Projection magnification M is defined by the expression of M=b/a. Such a projector does not form a focused image on the screen 200 unless the focal distance f of the projection lens optical system 550 is adjusted each time the projection distance b is changed or the projection magnification M is changed. In the case where the image is focused on the screen 200 located at the position represented by the solid line, if the screen 200 is moved to the position represented by the dashed line, the “blur due to defocusing” occurs on the screen 200 at such a position.

By contrast, the projector 100 according to the present disclosure forms an image without converging light beams, radiating from points in the primary image (the object surface) at various angles, to corresponding points on the screen 200. Therefore, the “blur due to defocusing” does not occur.

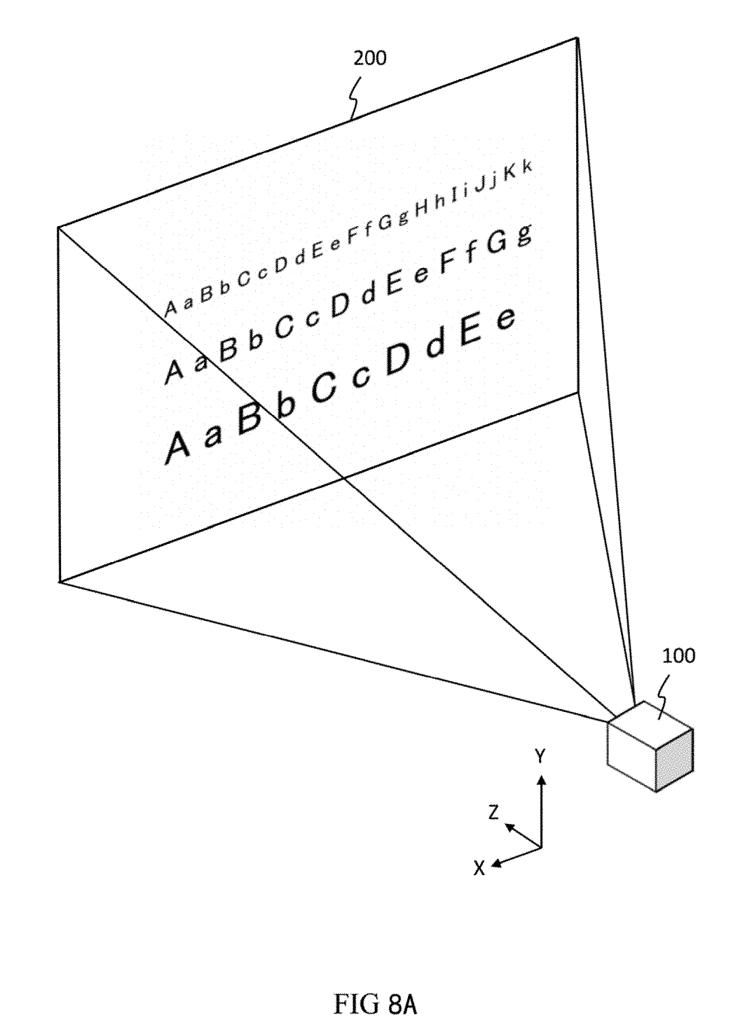

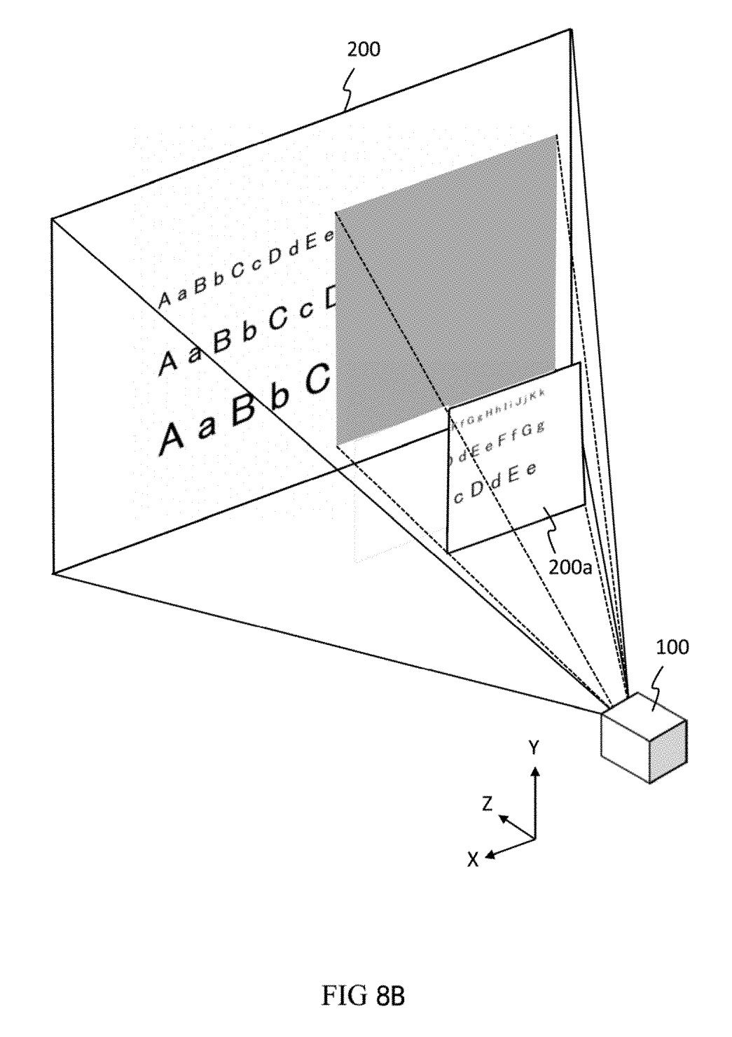

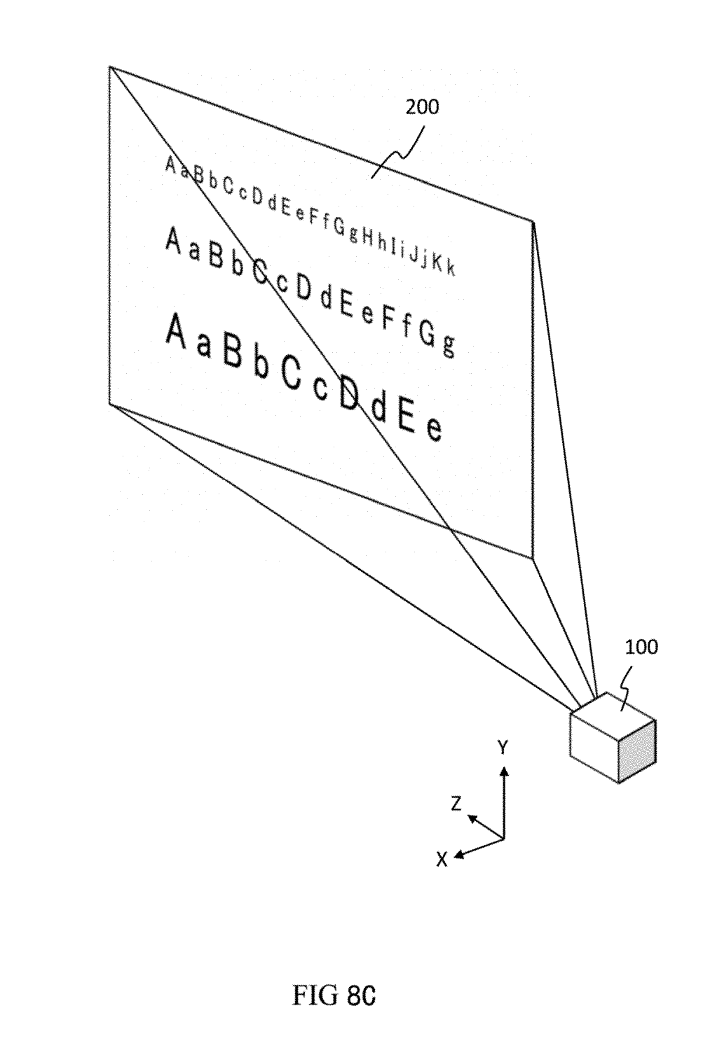

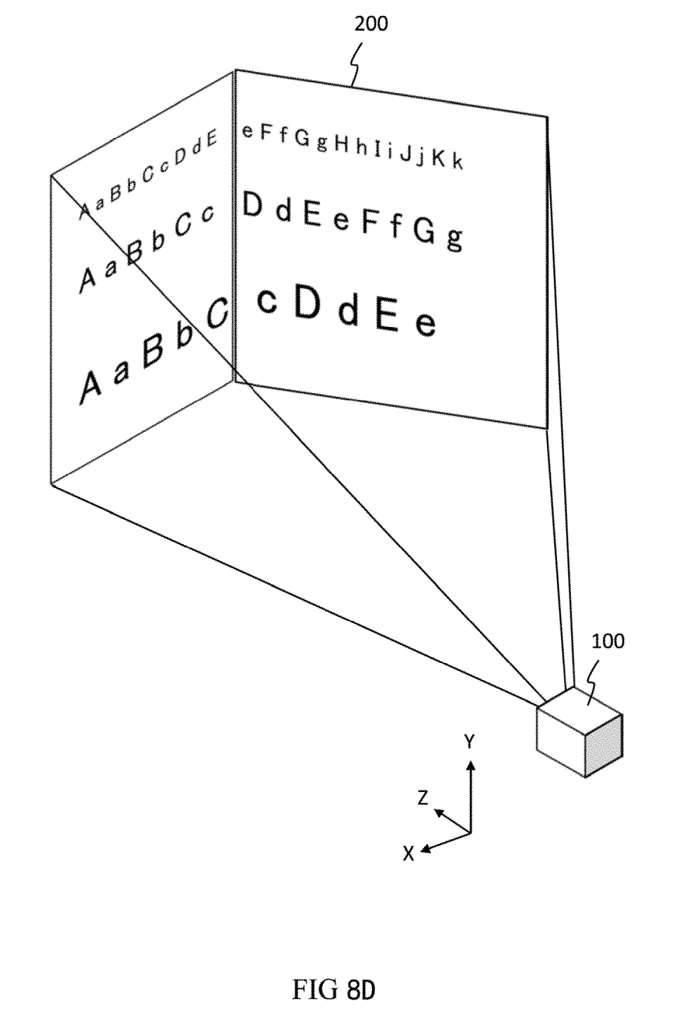

FIG. 8A is an isometric view schematically showing an example in which text data is projected and displayed on the screen 200 by use of the projector 100 according to the present disclosure. FIG. 8B is an isometric view showing a state where a part of a bundle of light beams output from the projector 100 is blocked by another screen 200a. As can be seen from FIG. 8B, images with no defocusing are formed on both of the two screens 200 and 200a located at different distances from the projector 100.

FIG. 8C schematically shows a state where the screen 200 is inclined. In this state, the distance from the projector 100 to the screen 200 is significantly different in accordance with the position in the screen 200. Even in such a case, an image with no defocusing is formed at any position in the screen 200.

FIG. 8D is an isometric view showing an example in which an image is displayed on a screen 200 that is not flat but is folded in the middle. A typical example of such a screen 200 is wall surfaces perpendicular to each other at a corner of a room. In general, wall surfaces are not always flat. Even in the case where an object surface having concaved and convexed portions, a stepped portion or a curved portion is used as the screen 200, an image with no defocusing is formed at any position in such an object surface.

In actuality, the characters displayed on the screen 200 are larger as the distance from the projector 100 is longer. In the figures referred to above, the size of the characters is not changed in accordance with the distance, for the sake of simplicity.

As can be seen from the above, the projector according to the present disclosure forms a clear image on an object having a shape on which a conventional projector as shown in FIG. 7 cannot form an image properly, and thus realizes projecting mapping. The projector according to the present disclosure does not use a method of scanning the screen with one or several laser beams at a high speed, but uses a method of irradiating an object such as a screen or the like with a large number of light beams at the same time. Therefore, even if the intensity of each of the light beams is suppressed to a low level safe to the human eye, the image displayed on the object such as a screen or the like is sufficiently bright. The power of the light beams is distributed. Therefore, even if, for example, a human who is in front of the screen displaying the projected image is directed toward the projector and his/her face is irradiated with some of the light beams, there is almost no need to worry about the adverse influence of the laser light entering the pupil.

### EMBODIMENTS

Hereinafter, embodiments of a projector according to the present disclosure will be described. Unnecessarily detailed descriptions may be omitted. For example, a well known element, component or state may not be described in detail, or substantially the same structure may not be described in repetition. This is to avoid the following description from being unnecessarily redundant and to make the description easier to understand for a person of ordinary skill in the art. The present inventor provides the attached drawings and the following description for a person of ordinary skill in the art to fully understand the present disclosure. It is not intended to limit the scope of the subject of the claims by the drawings or the description.

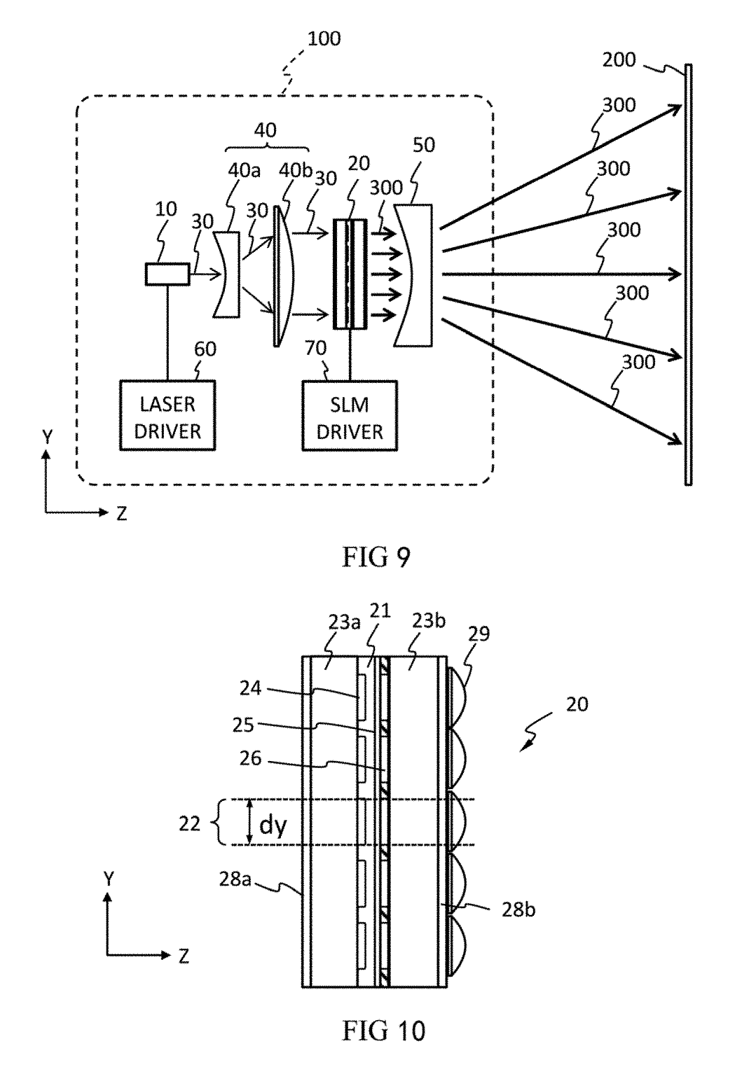

FIG. 9 is a cross-sectional view schematically showing an example of structure of the projector 100 in a non-limiting illustrative embodiment according to the present disclosure. The projector 100 projects an image on an object such as the screen 200 or the like, and includes a transmissive spatial light modulator 20 for forming a two-dimensional pattern for defining an image, and a laser light source 10 for irradiating the spatial light modulator 20 with laser light. The laser light source 10 is supplied with a driving current from a laser driver 60, so that a laser oscillation state of the laser light source 10 is controlled. The spatial light modulator 20 is driven by an SLM driver 70. The laser driver 60 and the SLM driver 70 are controlled by a computer (not shown) such as a microcontroller or the like. A part of, or the entirety of, the SLM driver 70 may be realized by a driving IC mounted on the spatial light modulator 20.

The projector 100 in this embodiment includes a beam shaping lens 40 and a projection magnification adjustment lens 50. In this example, the beam shaping lens 40 includes a concaved lens 40a and a convexed lens 40b. In the figure, the lenses are shown as elements having an illustrative shape for ease of understanding, and do not represent the actual shapes or sizes of the lenses. The projection magnification adjustment lens 50 is a single lens in the figure, but may be one lens or a “combined lens” including a group of various lenses. Similarly, the beam shaping lens 40 may be another form of “combined lens” or a single lens.

The projection magnification adjustment lens 50 adjusts the propagation direction of each light beam 300 to increase or decrease the interval between the irradiation points (light beam spots) arrayed on the screen 200. This operation does not require a work of focusing the light on the screen 200, unlike the image formation performed by the projection lens optical system 500 shown in FIG. 7.

The screen 200 may include microscopic concaved and convexed portions acting as Fresnel lenses or lenticular lenses in order to increase the luminance of the projected image. The screen 200 may be formed of a highly reflective cloth material (e.g., silk screen) or a highly diffuse-reflective cloth material (e.g., matte screen). The former material increases the luminance of the projected image, whereas the latter material realizes a wide viewing angle.

As described above with reference to FIG. 1, in this embodiment also, the laser light 30 radiating from the laser light source 10 is shaped by the lens sharping lens 40 including the concaved lens 40a and the convexed lens 40b as elements, and is incident on a rear surface of the spatial light modulator 20. In this application, the term “beam shaping” refers to changing at least one of the shape and the size of a cross-section of the laser light 30 perpendicular to the optical axis thereof. The shape of the cross-section is defined by the intensity distribution in the cross-section of the light beam 300. For example, the highest intensity value at the center of the cross-section is used as a reference value, and a border may be defined in the cross-section based on a portion having an intensity value that is half of the reference value.

FIG. 10 is a cross-sectional view schematically showing an example of general structure of the spatial light modulator 20 in this embodiment. The spatial light modulator 20 is a liquid crystal panel including a pair of transparent substrates 23a and 23b sealing a liquid crystal layer 21, a plurality of pixel electrodes 24 arranged in a matrix on the transparent substrate 23a, and a counter electrode 25 provided on the transparent substrate 23b. The transparent substrates 23a and 23b may be formed of glass or plastic. The pixel electrodes 24 and the counter electrode 25 are both formed of a transparent conductive material that transmits the laser light 30. Surfaces of the electrodes 24 and 25 are each covered with an alignment film (not shown), and regulate the alignment of liquid crystal molecules in the liquid crystal layer 21 in a desired direction. The liquid crystal layer 21 is formed of, for example, a nematic liquid crystal material (TN liquid crystal material), the alignment of which is regulated to be twisted. When necessary, the spatial light modulator 20 may include a color filter array 26. In the case where the spatial light modulator 20 is irradiated with “white” laser light 30 formed of multiplexed laser light in wavelengths ranges corresponding to the three primary colors of red (R), green (G) and blue (B), the color filter array 26 allows light beams 300 having different wavelengths to be output on a pixel-by-pixel basis. For example, referring to FIG. 2, three adjacent openings 22, for example, the openings 22a, 22b and 22c may respectively be covered with red, green and blue color filters. In the region other than the openings 22, a light-blocking black matrix may be formed. Display of a color image will be described below in detail. First, for the sake of simplicity, an example in which an image is displayed with single color light will be described.

The spatial light modulator 20 shown in FIG. 10 includes a first polarizer film 28a provided on the light incidence side of the transparent substrate 23a and a second polarizer film 28b provided on the light output side of the transparent substrate 23b. In an embodiment, a polarization transmission axis of the first polarizer film 28a and a polarization transmission axis of the second polarizer film 28b are perpendicular to each other to be in a crossed Nicols state. Transistors and metal interconnect lines (not shown) are formed on the transparent substrate 23a. The SLM driver 70 switches the transistor to control the voltage to be applied to the liquid crystal layer 21 in units of pixel regions. In this example, in a pixel in which a voltage is not applied between the pixel electrode 24 and the counter electrode 25, the polarization direction of the laser light 30 is rotated (polarization state is changed) while the laser light 30 is transmitted through the liquid crystal layer 21, and thus the laser light 30 is transmitted through the second polarizer film 28b (normally-on operation). By contrast, in a pixel in which a voltage is applied between the pixel electrode 24 and the counter electrode 25, the polarization direction of the laser light 30 is maintained while the laser light 30 is transmitted through the liquid crystal layer 21, and therefore, the laser light 30 is cut by the second polarizer film 28b. In the case where the transmission axis of the first polarizer film 28a and the transmission axis of the second polarizer film 28b are parallel to each other, an operation opposite to the above is performed (normally-off operation). In this manner, individual pixel regions act as the individual openings 22 of the spatial light modulator 20. The light transmittance of each of the openings 22 may be adjusted in an analog manner by the voltage applied between the corresponding pixel electrode 24 and the counter electrode 25.

The laser light 30 emitted from the laser light source 10 is usually linearly polarized in a predetermined direction. In the case where, for example, an edge-emitting semiconductor laser device is used as the laser light source 10, the laser light is polarized in a direction parallel to an active layer of the semiconductor laser device, in general. Therefore, it is preferred that the linear polarization direction of the laser light 30 is aligned with the direction of the transmission axis of the first polarizer film 28a in order to avoid unnecessary darkening from being caused by the first polarizer film 28a.

Utilizing that the laser light 30 is linearly polarized, the first polarizer film 28a may be omitted. Even without the first polarizer film 28a, the linearly polarized laser light 30 is incident on the spatial light modulator 20. The omission of the first polarizer film 28a prevents the laser light 30 from being absorbed by the polarizer film 28a on the light incidence side. Even in the case where the polarization direction of the laser light is aligned with the direction of the transmission axis of the polarizer film, about 1 to about 5% of the laser light is absorbed by the polarizer film to cause darkening. In the case where the first polarizer film 28a is omitted, the laser light 30 is utilized more efficiently. The omission of the first polarizer film 28a decreases the number of components and the production costs, and also contributes to decrease in the thickness of the spatial light modulator 20. Especially in the case where the spatial light modulator 20 is to be made super-compact to produce a mobile projector, it is an important advantage that a polarizer film is made unnecessary even though the polarizer film is about 0.2 mm thick.

In the spatial light modulator 20 realized by use of a liquid crystal panel using the TN liquid crystal material described above, the polarization direction of the laser light 30 incident on the spatial light modulator 20 and the transmission axis of the second polarizer film 28b provided on the light output side are adjusted to be perpendicular or parallel to each other. From the point of view of the contrast of a displayed image, it is preferred that the second polarizer film 28b is located such that the transmission axis thereof is perpendicular to the polarization direction of the laser light 30. With such a structure, high-contrast image display is realized with no phenomenon that black appears grayish.

The spatial light modulator 20 is not limited to having the above-described structure. The liquid crystal panel is available in various types including an in-plane switching type, a vertical alignment type and the like, and any type of liquid crystal panel is adoptable. Instead of the liquid crystal panel, a photographic slide having an image drawn thereon or a pair of glass plates having a specimen secured thereto for observation may be used as the spatial light modulator 20. The spatial light modulator 20 of such a type is usable to display a still image. A mechanism in which a spatial light modulator 20 is held so as to be replaceable with another type of spatial light modulator 20 may be adopted, so that an appropriate spatial light modulator 20 is selected from a large number of spatial light modulators 20 and is located on an optical path.

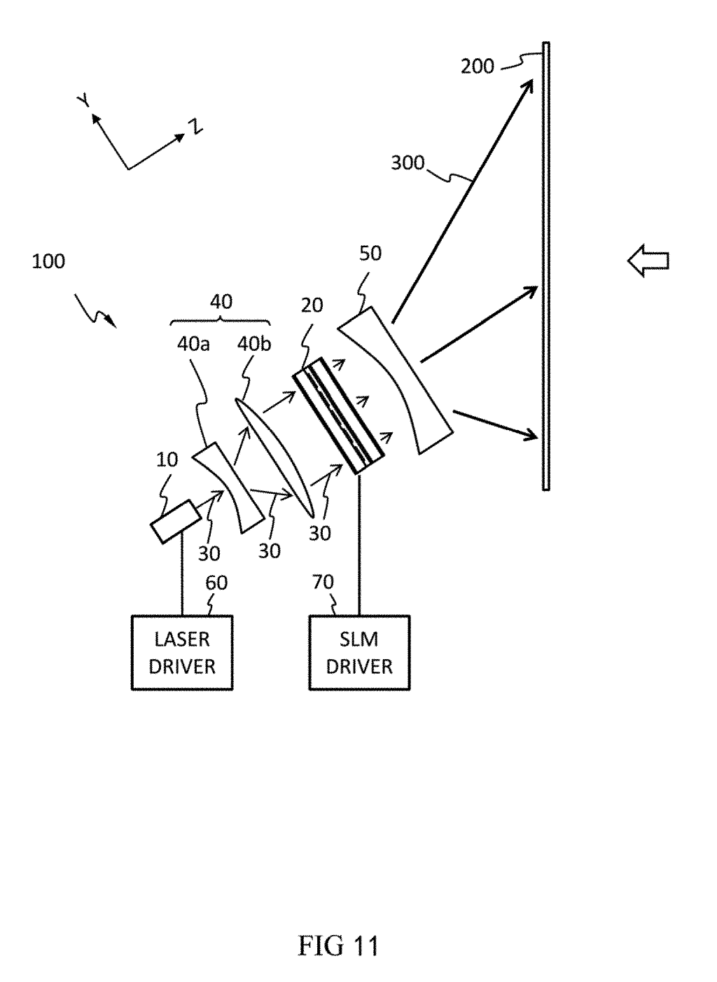

FIG. 11 shows an embodiment in which a viewer views the screen 200 in a direction of the white arrow; for instance, an example of structure of a rear projection-type TV set. The basic structure thereof is the same as that of the projector 100 shown in FIG. 9. In the example shown in FIG. 11, an image projected on the screen 200 is viewed by the viewer located on the side opposite to the projector 100 with respect to the screen 200. The screen 200 is not perpendicular but is significantly inclined with respect to the optical axis (Z axis) of the projector 100, but blur due to defocusing is not caused. In order to avoid the interval between the light beam spots (pixels) on the screen 200 from being changed in accordance with the projection distance, the adjustment lens 50 may have a function of adjusting the directions of the optical axes of the light beams 300. Alternatively, in order to avoid the displayed image from being distorted when the interval between the light beam spots (pixels) on the screen 200 is changed, a two-dimensional pattern to be formed on the spatial light modulator 20 may be deformed in advance. Such deformation may be performed by correcting an image signal to be supplied to the SLM driver 70 by a computer (not shown).

A mirror may be located between the projector 100 and the screen 200. Such a mirror increases the degree of freedom in the orientation of the projector 100 and thus to make the housing of the TV set more compact.

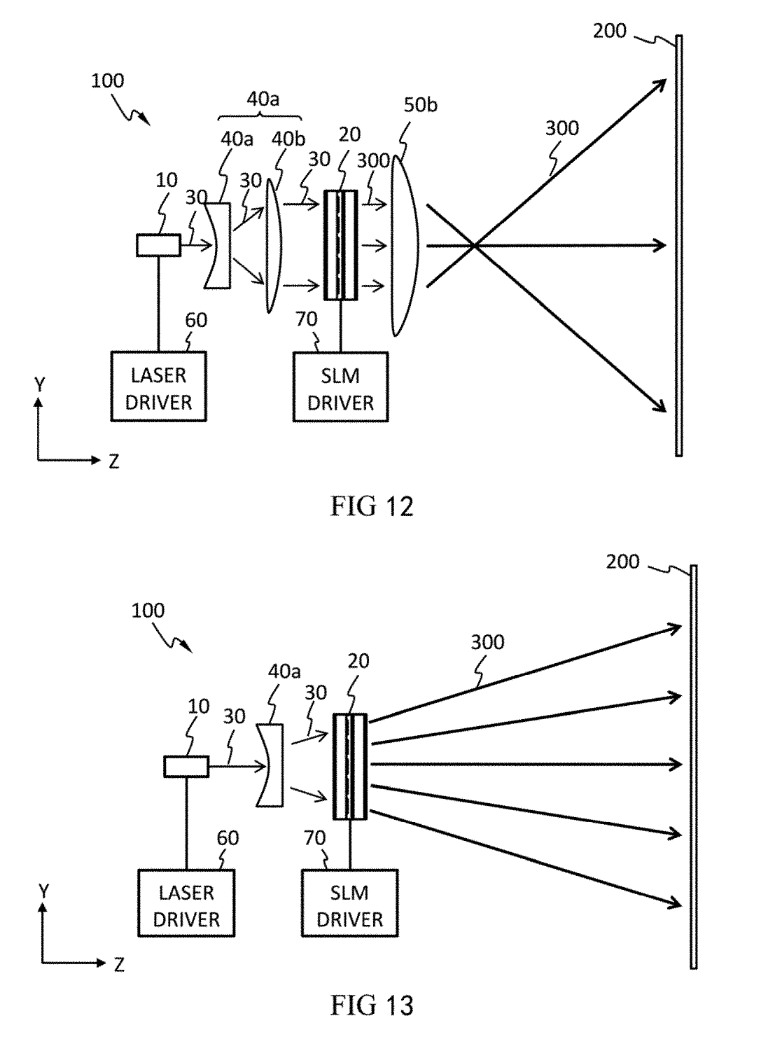

FIG. 12 is a cross-sectional view showing an example of structure of a projector 100 in still another embodiment. The projector 100 in this embodiment includes a convexed lens 50b, located between the spatial light modulator 20 and the screen 200, as a projection magnification adjustment lens. The convexed lens 50b enlarges an image.

FIG. 13 is a cross-sectional view showing an example of structure of a projector 100 in still another embodiment. The projector 100 in this embodiment does not include a magnification enlargement lens between the spatial light modulator 20 and the screen 200.

Instead, the concaved lens 40a located between the laser light source 10 and the spatial light modulator 20 is usable to enlarge an image. In this embodiment, the laser light 30 transmitted through the concaved lens 40a is incident on the spatial light modulator 20 in a state of a spherical wave, not a planar wave, to have the intensity thereof modulated spatially. The bundle of the laser beams 300 output from the spatial light modulator 20 is propagated in the space while diverging and are incident on the screen 200.

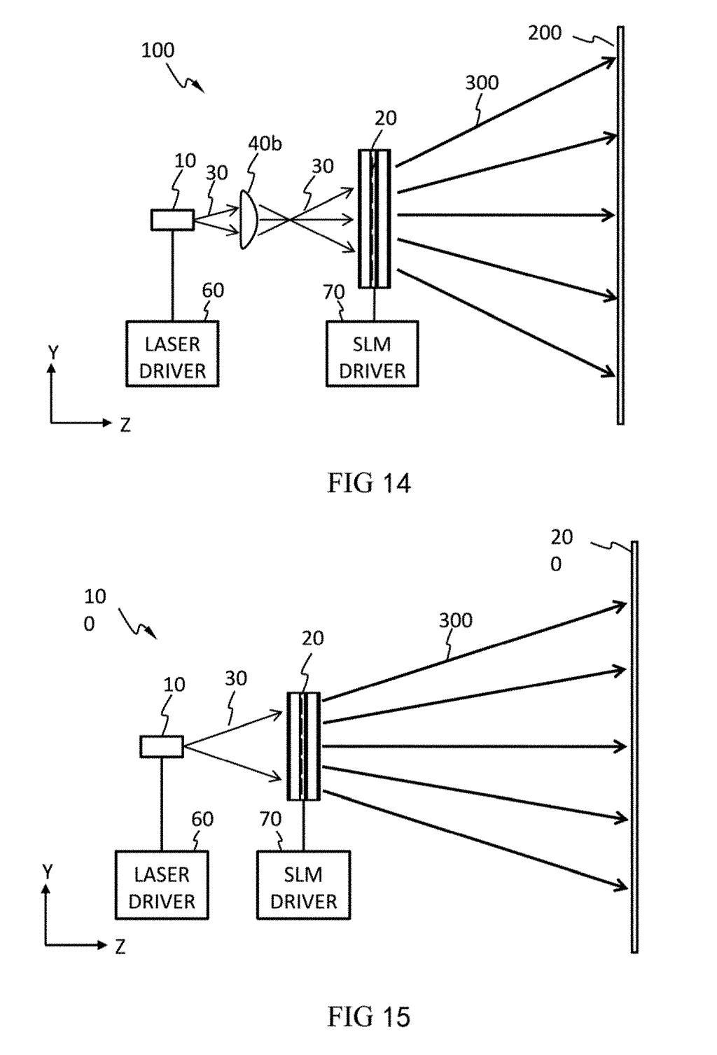

FIG. 14 is a cross-sectional view showing an example of structure of a projector 100 in still another embodiment. Unlike in the projector 100 in FIG. 13, in the projector 100 in this embodiment, the lens located between the laser light source 10 and the spatial light modulator 20 is the convexed lens 40b. The convexed lens 40b is also usable to enlarge the image.

FIG. 15 is a cross-sectional view showing an example of structure of a projector 100 in still another embodiment. The projector 100 in this embodiment does not include a magnification enlargement lens between the spatial light modulator 20 and the screen 20 or does not include a lens between the laser light source 10 and the spatial light modulator 20. In this embodiment, the laser light 30 emitted from the laser light source 10 diverges without being transmitted through a lens and is incident on the spatial light modulator 20. The bundle of the laser beams 300 output from the spatial light modulator 20 diverges as it is and reaches the screen 200.

The principle by which the laser light 30 emitted from the laser light source 10 diverges without being transmitted through a lens will be described below. In the case where the structure shown in FIG. 15 is adopted, an optical element such as a lens, a mirror, a diaphragm or the like may be optionally located on the optical path for the purpose of shaping the beams or adjusting the light intensity distribution. A mechanism that decreases the speckle of the laser light may be optionally provided. Such modifications may be performed in a similar manner in other embodiments.

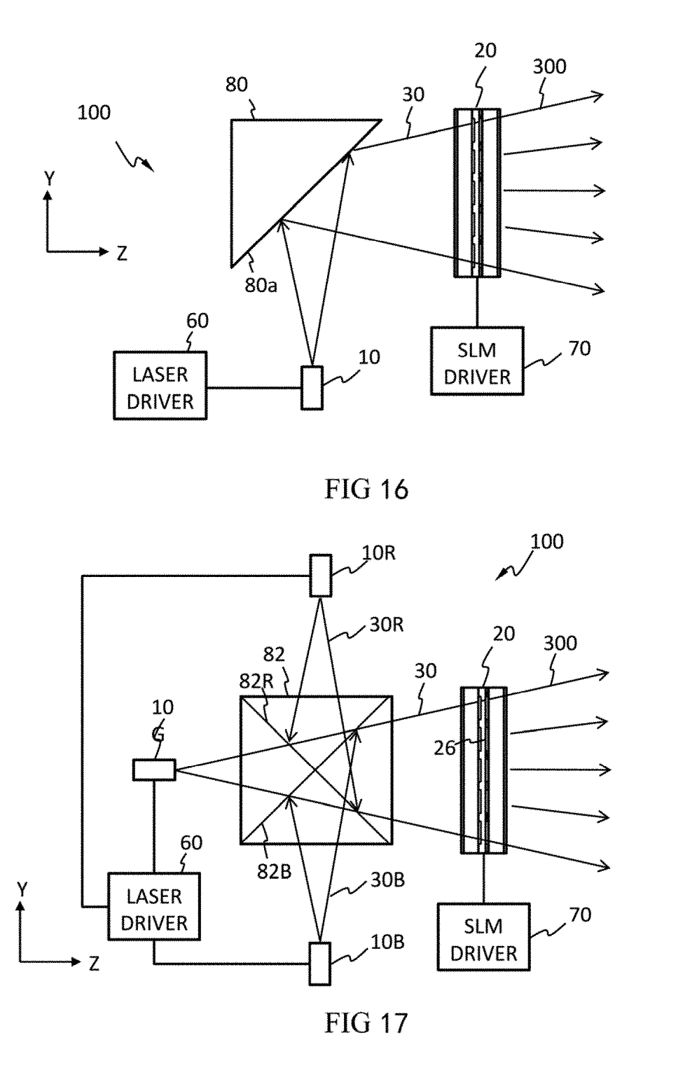

FIG. 16 is a cross-sectional view showing an example of structure of a projector 100 in still another embodiment. In this embodiment, a mirror 80 is located on the optical path to shorten the length of the projector 100 in the Z-axis direction.

In each of the above-described embodiments, the projector 100 includes a single laser light source 10. The projector 100 may include a plurality of laser devices as the laser light source 10. Such a plurality of laser devices may oscillate at different wavelengths to emit laser light of different colors, so that a color still image or a color moving image is displayed.

In order to display a full color image, any of the following structures may be adopted.

Structure (1): A liquid crystal panel including a color filter array is adopted as a spatial light modulator, and the spatial light modulator is irradiated with red, green and blue laser light.

Structure (2): A liquid crystal panel not including a color filter array is adopted as a spatial light modulator, and the spatial light modulator is sequentially irradiated with red, green and blue laser light (field sequential method).

Structure (3): Three liquid crystal panels not including a color filter array are adopted as spatial light modulators, and the spatial light modulators are respectively irradiated with red, green and blue laser light (three panel method).

First, with reference to FIG. 17, an example of the structure (1) will be described.

A projector 100 of the structure (1) includes, as the laser light source, a first laser device 10R oscillating in a first wavelength range, a second laser device 10G oscillating in a second wavelength range, and a third laser device 10B oscillating in a third wavelength range. In this example, the first wavelength range, the second wavelength range and the third wavelength range respectively corresponding to red (R), green (G) and blue (B). The first laser device 10R, the second laser device 10G and the third laser device 10B may respectively be, for example, a red semiconductor laser device oscillating at a wavelength of 650 nm, a green semiconductor laser device oscillating at a wavelength of 515 nm to 530 nm, and a blue semiconductor laser device oscillating at a wavelength of 450 nm. As the red semiconductor laser device, for example, an AlGaInP-based laser diode is preferably usable. As the green and blue semiconductor laser devices, GaN-based laser diodes having different compositions are usable. As the second laser device 10G, a DPSS (Diode Pumped Solid State) laser device including a semiconductor laser device emitting infrared light and a wavelength conversion element may be used. Infrared light having a wavelength of 808 nm generated by the infrared semiconductor laser device excites a laser crystal such as an Nd:YVO₄ crystal, a Yb:YAG crystal or the like to generate infrared laser light having a wavelength of, for example, 1064 nm. This infrared laser light may be incident on a nonlinear optical crystal such as a KTP (KTiOPO₄) crystal or the like, so that green laser light having a wavelength of 532 nm as a second harmonic is generated.

The projector 700 shown in FIG. 17 includes a dichroic prism 82. The dichroic prism 82 includes a red reflecting plane 82R selectively reflecting red light and a blue reflecting plane 82B selectively reflecting blue light. The dichroic prism 82 is used, so that red laser light 30R and blue laser light 30B are respectively reflected by the red reflecting plane 82R and the blue reflecting plane 82B, whereas the green laser light 30G is transmitted as it is. The three colors of laser light are synthesized to form the white laser light 30. Instead of the dichroic prism 82, a red reflecting dichroic mirror and a blue reflecting dichroic mirror may be used to synthesize the red, blue and green laser light 30R, 30B and 30G.

When the synthesized white laser light 30 is incident on a red filter of the color filter array in the spatial light modulator 20, only the red laser light is selectively transmitted through the red filter. Similarly, when the synthesized white laser light 30 is incident on a green filter of the color filter array, only the green laser light is selectively transmitted through the green filter. When the synthesized white laser light 30 is incident on a blue filter of the color filter array, only the blue laser light is selectively transmitted through the blue filter.

Color balancing is performed such that the white laser light synthesized by the dichroic prism 82 exhibits a predetermined color temperature. The color balancing may be realized by adjusting the optical output power of each of the laser light sources 10R, 10G and 10B by use of the laser driver 60. Alternatively, an ND (neutral density) filter may be located on the optical path when necessary to darken the laser light 30R, 30G and 30B. In order to adjust the optical output power of each of the laser light sources 10R, 10G and 10B, the laser oscillation pulse width may be modulated to adjust the duty ratio for each of the colors. In the case where this method is adopted, the laser light 30 irradiating the spatial light modulator 20 is not always white precisely, and there may be a time duration when either one or two of the red, green and blue laser light 30R, 30G and 30G are incident on the spatial light modulator 20. An important point is that a full color image natural to the human eye is viewed.

The laser light is very highly monochromatic, unlike light emitted from an LED or a fluorescent body. Therefore, the “white” laser light 30 formed by synthesizing red, blue and green laser light 30R, 30B and 30G does not have a broad spectrum and exhibits sharp peaks at three wavelengths, unlike the light emitted from a white LED. The color filter of each color on which the “white” laser light 30 is incident selectively transmits laser light of one wavelength among the three wavelengths. Therefore, each of the light beams 300 output from the spatial light modulator 20 also has a sharp peak. For this reason, the projector according to the present disclosure, even if adopting a liquid crystal panel including a color filter array, enlarges the color region as compared with the conventional projector using a high luminance lamp or an LED.

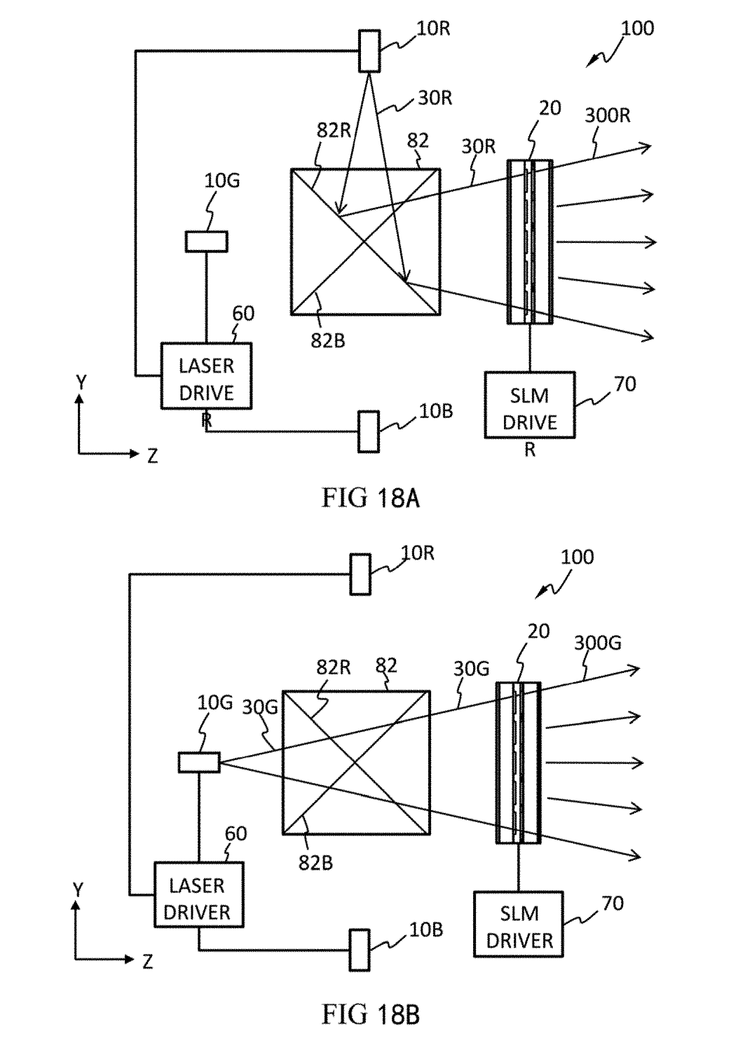

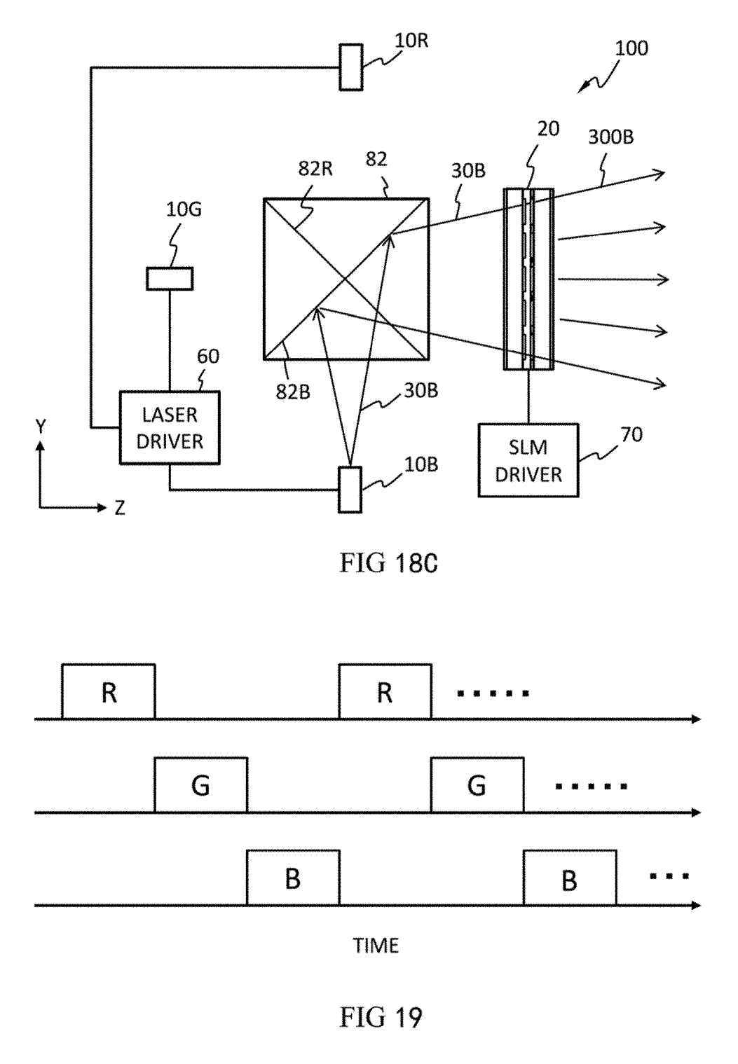

Now, with reference to FIG. 18A, FIG. 18B, FIG. 18C and FIG. 19, an example of the structure (2) will be described. The structure (2) realizes the field sequential method.

The basic structure thereof is substantially the same as that of the projector 100 shown in FIG. 17. One of differences is that the spatial light modulator 20 in this structure does not include a color filter array.

First, FIG. 18A will be referred to. In a state shown in the figure, the red laser light 30R radiates from the first laser device 10R, whereas no laser light radiates from the second laser device 10G or the third laser device 10B. The red laser light 30R emitted from the first laser device 10R is reflected by the red reflecting plane 82R of the dichroic prism 82 to irradiate the spatial light modulator 20. The red laser light 30R is spatially modulated to form a bundle of red light beams 300R. The bundle of the red light beams 300R forms a sub frame image.

Next, FIG. 18B will be referred to. In a state shown in the figure, the green laser light 30G radiates from the second laser device 10G, whereas no laser light radiates from the first laser device 10R or the third laser device 10B. The green laser light 30G emitted from the second laser device 10G is transmitted through the red reflecting plane 82R and the blue reflecting plane 82B of the dichroic prism 82 to irradiate the spatial light modulator 20. The green laser light 30G is spatially modulated to form a bundle of green light beams 300G. The bundle of the green light beams 300G forms another sub frame image.

Next, FIG. 18C will be referred to. In a state shown in the figure, the blue laser light 30B radiates from the third laser device 10B, whereas no laser light radiates from the first laser device 10R or the second laser device 10G. The blue laser light 30B emitted from the third laser device 10B is reflected by the blue reflecting plane 82B of the dichroic prism 82 to irradiate the spatial light modulator 20. The blue laser light 30B is spatially modulated to form a bundle of blue light beams 300B. The bundle of the blue light beams 300B forms still another sub frame image.

The above-described operation is performed in repetition. FIG. 19 schematically shows lit-up states of the laser light sources 10R, 10G and 10B. In FIG. 19, the rectangles surrounding the characters of “R”, “G” and “B” respectively represent the time durations in which the laser light sources 10R, 10G and 10B perform laser oscillation to emit the laser light. As shown in FIG. 19, the laser light sources 10R, 10G and 10B are each switched to a lip-up state and a non-lit-up state in repetition periodically. One frame of full color image is formed of three sub frames of red, green and blue. The time durations in which the laser light sources 10R, 10G and 10B are lit up may be different from each other.

In the case where the field sequential method is adopted, different colors of laser light are sequentially transmitted through the pixel regions of the liquid crystal panel. Therefore, the pixels do not need to be divided for each color. For this reason, a liquid crystal panel of the field sequential method requires only ⅓ of the number of pixels (the number of the openings) of a liquid crystal panel of a color filter array method. This is highly useful to enlarge the size of individual pixels to decrease the effect of diffraction, or to decrease the surface area of the liquid crystal panel. Since the step of forming the color filter array in the liquid crystal panel is not needed, the production cost is decreased. Thus, a liquid crystal panel having a high light transmittance may be adopted at low cost.

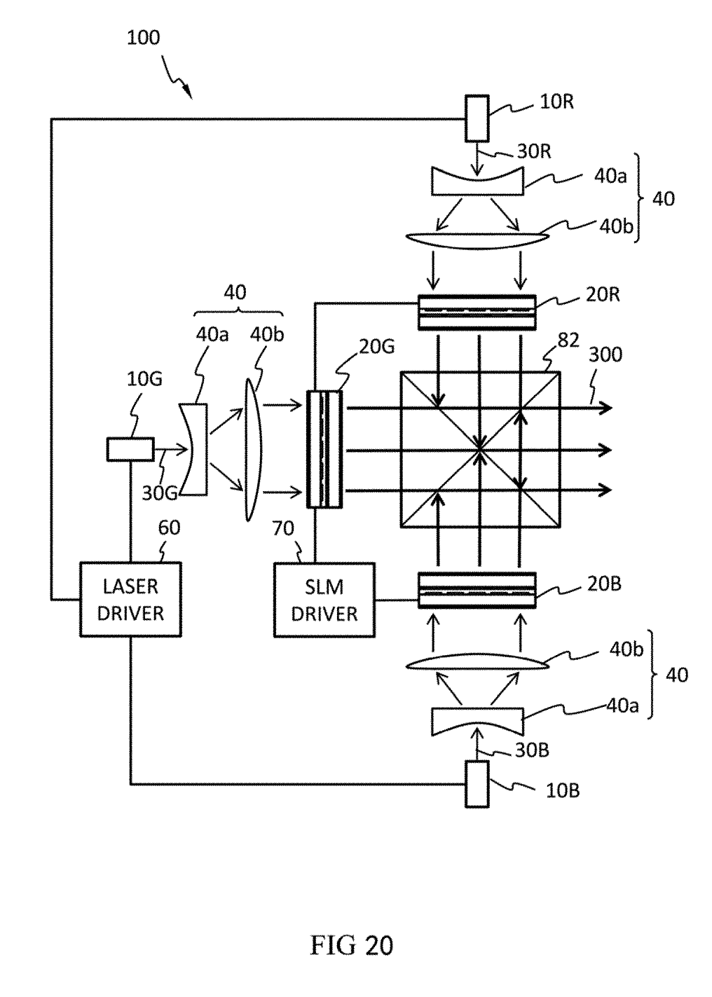

Now, with reference to FIG. 20, an example of the structure (3) will be described. A projector 100 in the structure (3) includes three spatial light modulators 20R, 20G and 20B. None of the three spatial light modulators 20R, 20G and 20B includes a color filter array. The spatial light modulators 20R, 20G and 20B are irradiated with different wavelengths of laser light. Specifically, the spatial light modulator 20R is irradiated with the red laser light 30R emitted from the laser light source 10R. Similarly, the spatial light modulator 20G is irradiated with the green laser light 30G emitted from the laser light source 10G. The spatial light modulator 20B is irradiated with the blue laser light 30B emitted from the laser light source 10B.

In the projector 100 shown in FIG. 20, bundles of laser beams output from the spatial light modulators 20R, 20G and 20B are synthesized by the dichroic prism 82.

In this manner, a color image may be formed by use of a plurality of laser devices having different oscillation wavelength ranges. The colors of the laser light used for the synthesis are not limited to the three primary colors of light. Laser light having a wavelength corresponding to a color different from red, green or blue may be additionally used. The color region may be further expanded by use of a larger number of primary colors. As described above, the laser light is very highly monochromatic. Therefore, the color region is expanded as compared with the case of using a projector using a conventional light source. Thus, the color reproducibility of the displayed image is significantly improved.

The basic structure of the projector 100 shown in FIG. 20 is substantially the same as that of the basic structure of the projector 100 shown in FIG. 9. Alternatively, the basic structure of the projector 100 shown in any of FIG. 12 through 15 may be adopted. Especially, the basic structure of the projector 100 shown in FIG. 15 does not require a complicated optical lens system, and thus is suitable to decrease the size of the projector.

Hereinafter, an example of structure and the principle of operation of the laser light source 10 that realizes the projector 100 shown in FIG. 15 will be described. As the laser light source 10, a semiconductor laser device is preferably usable. A reason for this is that laser light emitted from a semiconductor laser device has a property of diverging by the effect of diffraction of its own. Hereinafter, the effect of diffraction of a semiconductor laser device will be described.

<Effect of Diffraction of a Semiconductor Laser Device>

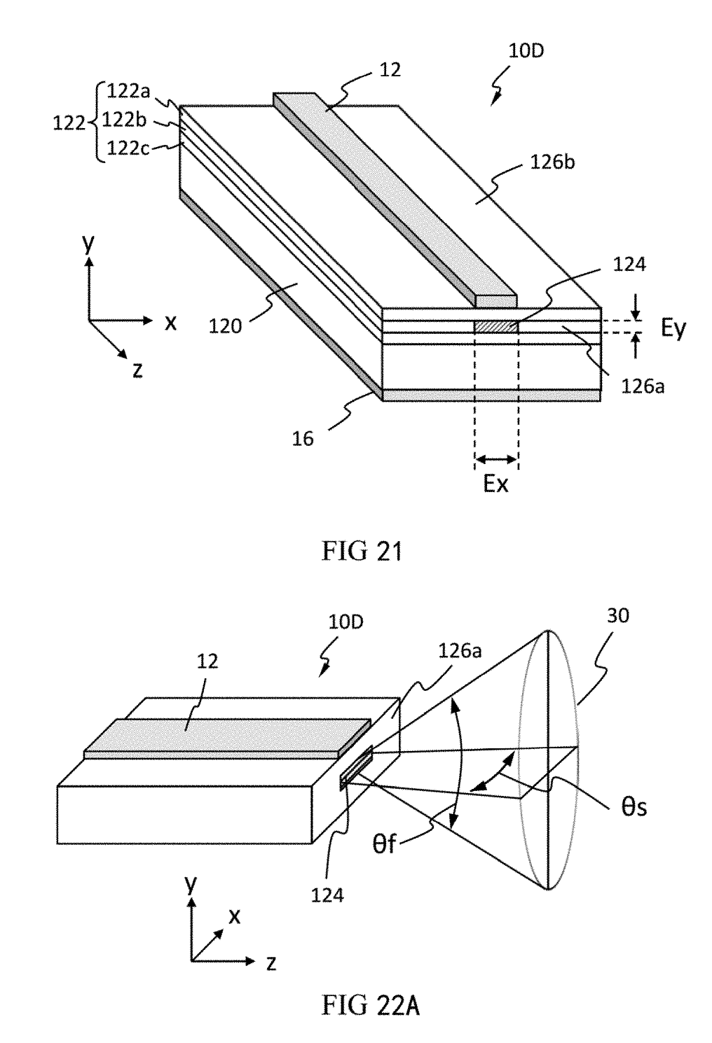

FIG. 21 is an isometric view schematically showing a basic structure of a typical semiconductor laser device. The figure shows coordinate axes including an x axis, a y axis and a z axis perpendicular to each other. The coordinate axes are inherent to the semiconductor laser device, and are different from the coordinate axes inherent to the projector. In order to distinguish these coordinate axes, the former coordinate axes are represented by x, y and z as the lowercase, whereas the latter coordinate axes are represented by X, Y and Z as the uppercase.

A semiconductor laser device 10D shown in FIG. 21 includes a semiconductor multilayer structure 122 having an end face (facet) 126a including a light emitting region (emitter) 124 emitting laser light. In this example, the semiconductor multilayer structure 122 is supported on a semiconductor substrate 120, and includes a p-side cladding layer 122a, an active layer 122b, and an n-side cladding layer 122c. A striped p-side electrode 12 is provided on a top surface 126b of the semiconductor multilayer structure 122. An n-side electrode 16 is provided on a rear surface of the semiconductor substrate 120. An electric current of a level exceeding a threshold value flows in a predetermined region of the active layer 122b from the p-side electrode 12 toward the n-side electrode 16, so that laser oscillation occurs. The end face 126b of the semiconductor multilayer structure 122 is covered with a reflective film (not shown). Laser light is output outside from a light emission region 124 through the reflective film.

The structure shown in FIG. 21 is merely a typical example of structure of the semiconductor laser device 10D, and is simplified for concise description. This example of simplified structure does not limit, in any way, this embodiment according to the present disclosure described below in detail. In the other drawings, the elements such as the n-side electrode 16 and the like may be omitted for the sake of simplicity.

In the semiconductor laser device 10D shown in FIG. 21, the end face 126a of the semiconductor multilayer structure 122 is parallel to an xy plane. Therefore, the laser light is emitted in the z-axis direction from the light emission region 124. An optical axis of the laser light is parallel to the z-axis direction. The light emission region 124 has, in the end face 126a, a size Ey in a direction parallel to the layer-layer-stacking direction (size in the y-axis direction) of the semiconductor multilayer structure 122 and a size Ex in a direction perpendicular to the layer-layer-stacking direction (size in the x-axis direction). In general, there is the relationship of Ey<Ex.

The size Ey of the light emission region 124 in the y-axis direction is defined by the thickness of the active layer 122b. The thickness of the active layer 122b is usually about half or less of the laser oscillation wavelength. By contrast, the size Ex of the light emission region 124 in the x-axis direction is defined by the width of a structure, confining the electric current or light, contributing to the laser oscillation, in a horizontal lateral direction (x-axis direction); in the example shown in FIG. 21, is defined by the width of the striped p-side electrode 12. In general, the size Ey of the light emission region 124 in the y-axis direction is about 0.1 μm or smaller, whereas the size Ex of the light emission region 124 in the x-axis direction is larger than 1 μm. In order to increase the optical output, it is effective to increase the size Ex of the light emission region 124 in the x-axis direction. The size Ex in the x-axis direction may be set to, for example, 50 μm or larger.

In this specification, Ex/Ey is referred to as the “aspect ratio” of the light emission region. The aspect ratio (Ex/Ey) of a high-output semiconductor laser device may be set to, for example, 50 or higher, or may be set to 100 or higher. In this specification, a semiconductor laser device having an aspect ratio (Ex/Ey) of 50 or higher is referred to as a “broad area-type semiconductor laser device”. In such a broad area-type semiconductor laser device, the horizontal lateral mode of oscillation is often a multiple mode, not a single mode.

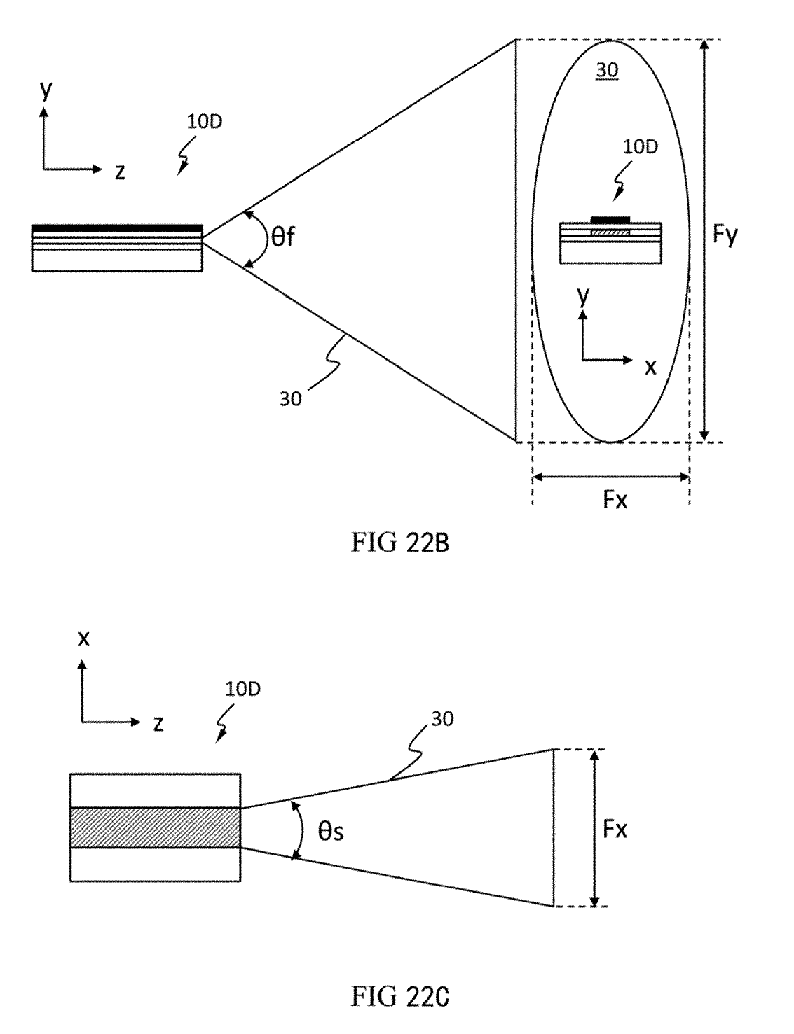

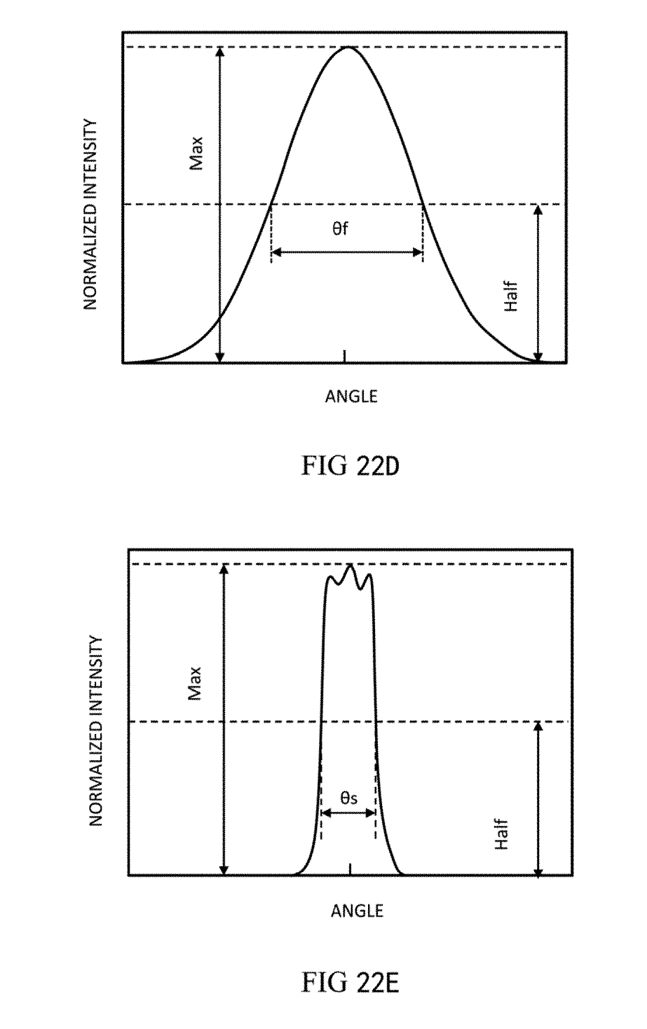

FIG. 22A is an isometric view schematically showing spreading (divergence) of the laser light that is output from the light emission region 124 of the semiconductor laser device 10D. FIG. 22B is a side view schematically showing the divergence of the laser light 30. FIG. 22C is a plan view schematically showing the divergence of the laser light 30. FIG. 22B also shows, in a right part thereof, a front view of the semiconductor laser device 10D as seen in a positive direction along the z-axis direction, for reference.

The size, in the y-axis direction, of a cross-section of the laser light 30 is defined by length Fy, and the size, in the x-axis direction, of the cross-section is defined by length Fx. Fy is a full width at half maximum (FWHM) in the y-axis direction on the basis of the light intensity of the laser light 30 at the optical axis of the laser light 30 in a plane crossing the optical axis. Similarly, Fx is a full width at half maximum (FWHM) in the x-axis direction on the basis of the light intensity of the laser light 30 at the optical axis of the laser light 30 in the above-described plane.

The divergence of the laser light 30 in the y-axis direction is defined by angle θf, and the divergence of the laser light 30 in the x-axis direction is defined by angle θs. θf is a full width at half maximum in a yz plane on the basis of the light intensity of the laser light 30 at a point which is on a spherical surface that is equidistant from the center of the light emission region 124 and at which the spherical surface crosses the optical axis of the laser light 30. Similarly, θs is a full width at half maximum in an xz plane on the basis of the light intensity of the laser light 30 at a point which is on the spherical surface that is equidistant from the center of the light emission region 124 and at which the spherical surface crosses the optical axis of the laser light 30.

FIG. 22D is a graph showing an example of divergence of the laser light 30 in the y-axis direction. FIG. 22E is a graph showing an example of divergence of the laser light 30 in the x-axis direction. In the graphs, the vertical axis represents the normalized light intensity, and the horizontal axis represents the angle. The laser light 30 exhibits a peak value on an optical axis parallel to the z-axis direction. As can be seen from FIG. 22D, the light intensity in a plane parallel to the yz plane including the optical axis of the laser light 30 generally shows a Gaussian distribution. By contrast, as shown in FIG. 22E, the light intensity in a plane parallel to the xz plane including the optical axis of the laser light 30 shows a narrow distribution having a relatively flat top portion. This distribution often includes a plurality of peaks caused by the multiple-mode oscillation.

The lengths Fy and Fx defining the size of the cross-section of the laser light 30 and the angles θf and θs defining the divergence of the laser light 30 may be defined in a different manner from the above.

As shown in the figures, the divergence of the laser light 30 output from the light emission region 124 has anisotropy, and in general, there is the relationship of θf>θs. A reason why θf is larger is that the size Ey of the light emission region 124 in the y-axis direction is shorter than, or equal to, the wavelength of the laser light 30 and therefore, strong diffraction is caused in the y-axis direction. By contrast, the size Ex of the light emission region 124 in the x-axis direction is sufficiently longer than the wavelength of the laser light 30 and therefore, diffraction is not easily caused in the x-axis direction.

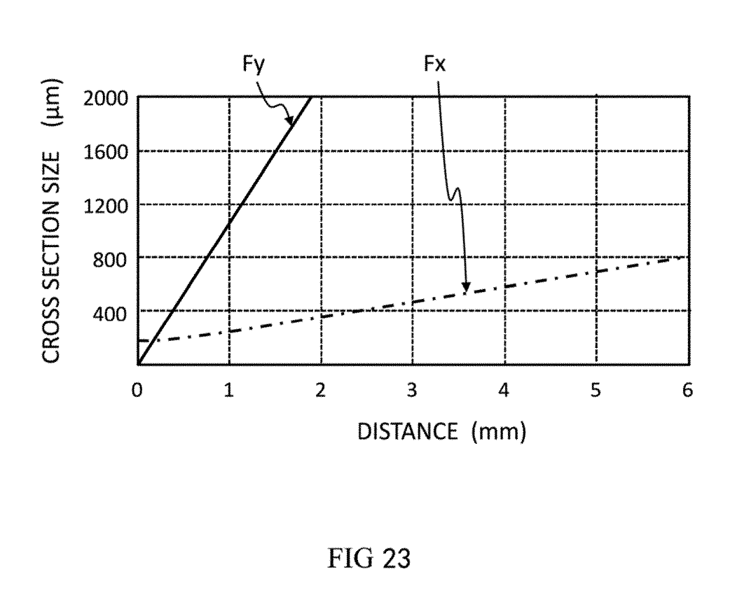

FIG. 23 is a graph showing the relationship between the distance from the light emission region 124 (position in the z-axis direction) and each of the size Fy in the y-axis direction and the size Fx in the x-axis direction of the cross-section of the laser light 30. As can be seen from FIG. 23, the cross-section of the laser light 30 exhibits a near field pattern (NFP) relatively long in the x-axis direction in the vicinity of the light emission region 124, but exhibits a far field pattern (FFP) long in the y-axis direction in a region sufficiently far from the light emission region 124.

As can be seen, as being farther from the light emission region 124, the cross-section of the laser light 30 is enlarged faster in the y-axis direction and slower in the x-axis direction. Therefore, regarding the coordinate axes of the semiconductor laser device 10D, the y-axis direction is referred to as a “fast-axis direction” and the x-axis direction is referred to as a “slow-axis direction”.

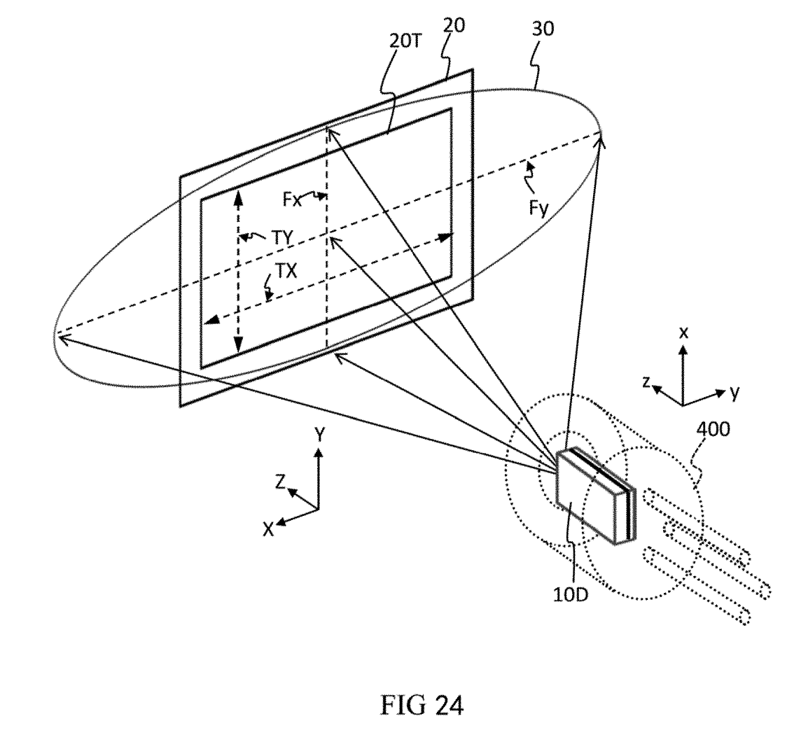

FIG. 24 is an isometric view showing an example of structure that is provided to realize the projector 100 shown in FIG. 15 by use of the semiconductor laser device 10D. In this example, the semiconductor laser device 10D is accommodated in a package 400. The package 400 includes a heat sink (not shown) to which the semiconductor laser device 10D is secured, metal lines supplying a driving current to the semiconductor laser device 10D, a system supporting these, and the like, which are well known and thus are not shown. The orientation of the package 400 is determined such that the semiconductor layer-stacking direction of the semiconductor laser device 10D (the y-axis direction, namely, the fast-axis direction) is perpendicular to the vertical direction in FIG. 24 (Y-axis direction). In FIG. 24, only a single semiconductor laser device 10D is shown. In the case where a plurality of the semiconductor laser devices 10D are used, the semiconductor layer-stacking directions of all the semiconductor laser devices 10D are aligned with the vertical direction (Y-axis direction).

As shown in FIG. 24, the laser light 30 output from the semiconductor laser device 10D has a shape, at a cross-section perpendicular to the optical axis (z-axis), in which the size Fy in the fast-axis (y-axis) direction is larger than the size Fx in the slow-axis (x-axis) direction. The laser light 30 having such an anisometric shape irradiates the spatial light modulator 20.

In the example shown in FIG. 24, a light modulation region (the entirety of the light transmission region) 20T, of the laser light 30, in the spatial light modulator 20 has a first size TX in the X-axis direction (horizontal direction) and a second size TY in the Y-axis direction (vertical direction) perpendicular to the X-axis direction. The first size TX is larger than the second size TY. In this example, the semiconductor laser device 10D is located such that the fast-axis (y-axis) direction thereof is aligned with the X-axis direction of the light modulation region 20T of the spatial light modulator 20. In other words, the semiconductor laser device 10D is located such that the semiconductor layer-stacking direction (the y-axis direction or the fast-axis direction) is perpendicular to a minimum size direction (the Ty direction, namely, the Y-axis direction) of the light modulation region 20T of the spatial light modulator 20. The laser light 30 emitted from the semiconductor laser device 10D is incident on the light modulation region 20T of the spatial light modulator 20 while a cross-section thereof perpendicular to the optical axis (z-axis) is enlarged, and the region irradiated with the laser light 30 includes the entirety of the light modulation region 20T. Such a structure may be adopted, so that the light modulation region 20T of the spatial light modulator 20 is effectively irradiated by use of the natural divergence of the laser light 30 emitted from the semiconductor laser device 10D. Therefore, the projector 100 is made compact and lightweight and is decreased in the production cost, while decreasing the loss of the light amount caused by the lens or the mirror.

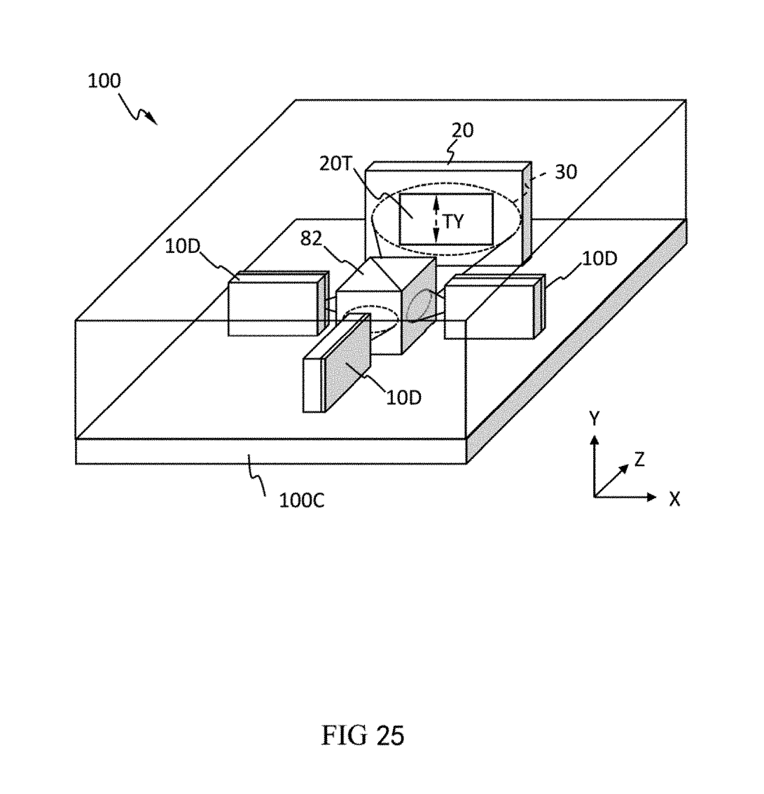

FIG. 25 is an isometric view schematically showing an example of structure in which three semiconductor laser devices 10D having different oscillation wavelengths are located in a housing of the projector 100. Different colors of the laser light 30 are synthesized by the dichroic prism 82 to irradiate the spatial light modulator 20. All the semiconductor laser devices 10D are located such that the semiconductor layer-stacking direction (fast-axis direction) is perpendicular to the minimum size direction (the Ty direction, namely, the Y-axis direction) of the light modulation region 20T of the spatial light modulator 20. With such a structure, the entirety of the light modulation region 20T of the spatial light modulator 20 is effectively irradiated by use of the natural divergence of the laser light 30 output from each of the semiconductor laser devices 10D. In the structure shown in FIG. 25, an optical element such as a mirror, a diaphragm or the like (not shown) may be located in the projector 100.

In uses requiring a high optical output, the chip area size of the semiconductor laser device 10D is now increasing. As shown in FIG. 25, all the semiconductor laser devices 10D may be located such that the semiconductor layer-stacking direction is parallel to a base 100C of the housing, so that the region of the base 100C that is occupied by the semiconductor laser devices 10D is decreased to make the projector 100 compact.

FIG. 25 does not show the package accommodating each of the semiconductor laser devices 10D. As the chip area size of each of the semiconductor laser devices 10D is increased, the size of the package may be kept to be relatively short in the semiconductor layer-stacking direction of the semiconductor laser device 10D and may be made relatively long in a direction perpendicular to the semiconductor layer-stacking direction. Therefore, even in the case where the semiconductor laser devices 10D are accommodated in housings, the positional arrangement shown in FIG. 25 contributes to the decrease in the size of the region occupied by the semiconductor laser devices 10D.

The laser light 30 emitted from the semiconductor laser device 10D is usually linearly polarized in the slow-axis (x-axis) direction. In the case where such a semiconductor laser device 10D is used, the light modulation region 20T of the spatial light modulator 20 is irradiated with the laser light 30 linearly polarized in the Y-axis direction. In the case where the spatial light modulator 20 is realized by a liquid crystal panel using an TN liquid crystal material described above, the transmission axis of the polarizer film provided on the light output side is set to be aligned with the X-axis direction or the Y-axis direction in accordance with whether the normally-on operation or the normally-off operation is to be performed. As described above, from the point of view of the contrast of the displayed image, it is preferred that the transmission axis of the polarizer film provided on the light output side is perpendicular to the polarization direction of the laser light 30 when the laser light 30 is incident on the spatial light modulator 20. In other words, it is preferred that the transmission axis of the polarizer film provided on the light output side is perpendicular to the minimum size direction (the Ty direction, namely, the Y-axis direction) of the light modulation region 20T. A reason for this is that with such an arrangement, a high contrast image is displayed with no phenomenon that black appears grayish.

A beam shaping lens such as a collimator lens or the like, or a diaphragm, may be located between the spatial light modulator 20 located as described above and the semiconductor laser device 10D, in order to adjust the cross-sectional shape or the light intensity distribution of the laser light 30. Even in the case where the structure shown in FIG. 24 or FIG. 25 is adopted, a projection magnification adjustment lens may still be provided on the light output side of the spatial light modulator 20.

In the case where the semiconductor laser device 10D is used as the laser light source 10, the light source is very small and the laser light diverges by the effect of diffraction of the semiconductor laser device 10D itself. Therefore, the projector is made significantly smaller than the conventional projector. The semiconductor laser device 10D is generally accommodated in a package having a diameter of 5.6 mm, 3.0 mm or the like when being provided as a product. The semiconductor laser device 10D accommodated in the package has a very small chip size, for example, has a size of 1.0 mm in the resonator length direction (z-axis direction), a size of 0.3 mm in the end face lateral direction (x-axis direction) and a size of 0.05 mm in the thickness direction (y-axis direction). Such a compact laser light source and a compact liquid crystal panel may be used, so that a compact projector for mobile use is realized. For color display, in the case where a structure including a color filter array described above is used, a liquid crystal panel having a size of, for example, 8 mm (width direction)×6 mm (length direction) may be adopted. The field sequential method allows the number of pixels required for display to be decreased to ⅓. Therefore, a super-compact liquid crystal panel having a size of, for example, 4 mm (width direction)×3 mm (length direction) or smaller may be adopted to further decrease the size of the projector. Such a projector may be attached to, for example, a display of a notebook computer, so that an image is projected in a focus-free manner and displayed on a desktop or a wall of a room. Such an example of structure may be easily realized by adopting a transmissive spatial light modulator, not a reflective spatial light modulator.

In the above-described examples, an edge-emitting semiconductor laser device, which emits laser light from an end face of a semiconductor stacking structure, is used as the semiconductor laser device 10D. The semiconductor laser device 10D adoptable for a projector according to the present disclosure is not limited to the semiconductor laser device in these examples. A surface-emitting semiconductor laser device may be used.

The projector according to the present disclosure is usable for a use other than for displaying a still image or a moving image visible to the human eye.

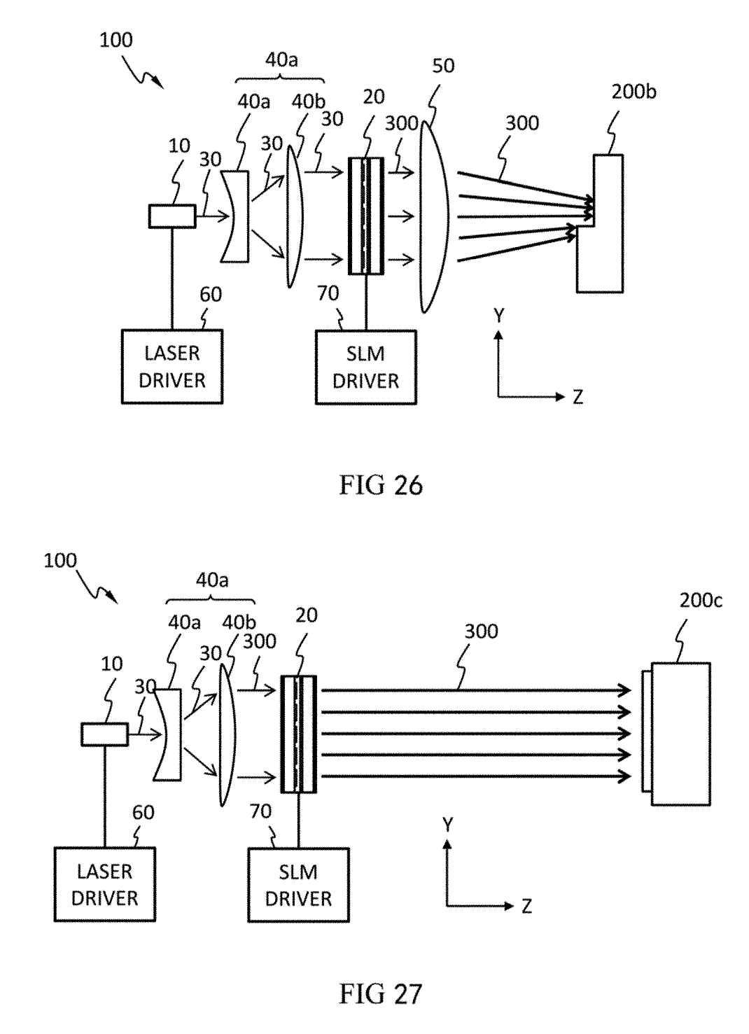

FIG. 26 shows an example of structure of an exposure device that projects an image on a work 200b having concaved and convexed portions or a curved portion at a surface thereof. The exposure device may utilize the property of being focus-free to expose a photosensitive material provided at a surface of a target in a mask-less manner, which is difficult by a conventional exposure device.

FIG. 27 shows an example of structure in which a bundle of light beams 300 is incident on a light receiving surface of a photo-receiving device 200c such as an image sensor or the like. A two-dimensional pattern formed by the spatial light modulator 20 is, for example, encoded to represent information to be transmitted. Such encoded information is reflected on a spatial intensity distribution represented by the bundle of light beams 300 output from the spatial light modulator 20. The photo-receiving device 200c detects the spatial intensity distribution represented by the bundle of light beams 300. Based on the output from the photo-receiving device 200c, a computer (not shown) decodes the above-mentioned information. As can be seen, the projector according to the present disclosure is applicable to an information transmission device.

In the examples shown in FIG. 26 and FIG. 27, the laser light may have a wavelength outside the visible light range. Laser light in an ultraviolet range or an infrared range is usable for the projector according to the present disclosure. The projector according to the present disclosure may, for example, irradiate a desired position in a photosensitive resin with light having an appropriate wavelength to realize 3D printing. The output of the light beam may be increased to locally raise the temperature at an irradiation point on an object to perform processing or surface treatment on the object.

From the point of view of decreasing the size and weight of the device, it is preferred to use a semiconductor laser device as the laser light source 10. The present invention is not limited to such an example. A part of, or the entirety of, the laser light source 10 may be formed of a laser device other than a semiconductor laser device. A high-output laser device such as another solid-state laser device having a high optical output, or a gas laser device or the like may be used. Use of a high-output laser device allows the projector to be used at a site where the projection distance is long, for example, indoors. Information communication of a larger capacity may be realized, or an object may be processed or surface-treated in a larger region at a higher speed.

In the case where a photographic slide (positive film), a specimen on a glass plate for observation, a silhouette artwork or the like is used as the spatial light modulator, the shape and the size of the “opening” may be varied in one spatial light modulator, unlike in a liquid crystal panel.

### INDUSTRIAL APPLICABILITY

The projector according to the present disclosure has a property of being focus-free utilized to be usable for various uses of projecting an image on an inclined screen or an object having concaved and convexed portions at a surface thereof. The target on which an image is to be projected is not limited to a screen, and may be any of a wide range of items including a wall, a glass item, a desktop, a building, a road, a vehicle, a part of a body of a creature (e.g., arm, palm, back, etc.) or the entirety of such a body, water drop or an assembly of powdery particles, a fluid, a semitransparent item, a photosensitive resin, an image sensor, and the like.

### REFERENCE SIGNS LIST

10 laser light source
10R first laser device
10G second laser device
10B third laser device
10D semiconductor laser device
12 p-side electrode of the semiconductor laser device
16 n-side electrode of the semiconductor laser device
18 incoherent light source
20, 20R, 20G, 20B spatial light modulator
20T light modulation region of the spatial light modulator
21 liquid crystal layer
22 opening (aperture)
23a, 23b transparent substrate
24 pixel electrode
25 counter electrode
26 color filter array
28a first polarizer film
28b second polarizer film
29 microlens array
30, 30R, 30G, 30B laser light
40 beam shaping lens
40a concaved lens
40b convexed lens
50 projection magnification adjustment lens
50b convexed lens (projection magnification adjustment lens)
60 laser driver
70 SLM driver
80 mirror
100 projector
120 semiconductor substrate
122 semiconductor multilayer structure
122a p-side cladding layer
122b active layer
122c n-side cladding layer
124 light emission region (emitter)
126a end face (facet)
126b top surface of the semiconductor multilayer structure
200 screen
200b work
200c photo-receiving device
250 liquid crystal panel
300, 300R, 300G, 300B light beam
400 package
550 projection lens optical system

1. A projector for projecting an image on an object in a focus-free manner, the projector comprising:
a transmissive spatial light modulator that forms a two-dimensional pattern for defining the image; and
a laser light source that irradiates the spatial light modulator with laser light;
wherein the spatial light modulator generates a bundle of a plurality of light beams, having a spatial intensity distribution of the two-dimensional pattern, from the laser light.

2. The projector of claim 1, wherein the projector causes the plurality of light beams generated by the spatial light modulator to be incident on the object to form, on the object, an image including, as pixels, irradiation points at which the object is irradiated with the light beams.

3. The projector of claim 1, wherein the spatial light modulator includes a plurality of openings respectively transmitting the plurality of light beams, and outputs one of the light beams from each of the openings.

4. The projector of claim 3, wherein the spatial light modulator changes a light transmittance of each of the openings in response to a driving signal.

5. The projector of claim 3, wherein:
the laser light emitted from the laser light source is incident on the spatial light modulator while enlarging a cross-section thereof perpendicular to an optical axis thereof; and
an angle at which the light beam is output from each of the openings of the spatial light modulator is constant for each of the openings regardless of the two-dimensional pattern.

6. The projector of claim 1, wherein:
the spatial light modulator includes a polarizer film only on a side on which the plurality of light beams are output; and
a polarization transmission axis of the polarizer film is perpendicular to a polarization direction of the laser light when the laser light is incident on the spatial light modulator.

7. The projector of claim 1, wherein:
the laser light source includes a plurality of laser devices including a first laser device oscillating in a first wavelength range and a second laser device oscillating in a second wavelength range, and a wavelength range of the laser light includes the first wavelength range and the second wavelength range; and
the spatial light modulator includes a color filter array selectively transmitting light in a different wavelength range at a different position in the color filter array.

8. The projector of claim 1, wherein:
the laser light source includes a plurality of laser devices including a first laser device oscillating in a first wavelength range and a second laser device oscillating in a second wavelength range; and
the laser light source sequentially irradiates the spatial light modulator with laser light in different wavelength ranges.

9. The projector of claim 7, wherein the plurality of laser devices include a third laser device oscillating in a third wavelength range.

10. The projector of claim 1, further comprising a projection magnification adjustment lens located between the object and the spatial light modulator.

11. The projector of claim 1, further comprising a microlens array located between the object and the spatial light modulator.

12. The projector of claim 1, further comprising a beam shaping lens located between the spatial light modulator and the laser light source.

13. The projector of claim 1, wherein:
the laser light source includes a semiconductor laser device emitting the laser light, the semiconductor laser device includes a semiconductor multilayer structure having an end face including a light emission region emitting the laser light, and the light emission region has a size in a fast-axis direction parallel to a layer-layer-stacking direction of the semiconductor multilayer structure and a size in a slow-axis direction perpendicular to the layer-layer-stacking direction; and
the laser light emitted from the semiconductor laser device has a shape, at a cross-section perpendicular to the optical axis thereof, in which a size in the fast-axis direction is larger than a size in the slow-axis direction, and the laser light having the shape irradiates the spatial light modulator.

14. The projector of claim 13, wherein:
an irradiation region, on the spatial light modulator, irradiated with the laser light has a first size in a first direction and a second size in a second direction perpendicular to the first direction, and the first size is larger than the second size; and
the fast-axis direction of the semiconductor laser device is aligned with the first direction of the irradiation region.

15. A projector for projecting an image on an object in a focus-free manner, the projector comprising:
a plurality of transmissive spatial light modulators each forming a two-dimensional pattern for defining the image; and
a plurality of laser light sources that respectively irradiate the plurality of spatial light modulators with laser light in different wavelength ranges;
wherein the plurality of spatial light modulators each generate a bundle of a plurality of light beams, having a spatial intensity distribution of the two-dimensional pattern, from the laser light.

16. A projector for projecting an image on an object in a focus-free manner, the projector comprising:
a spatial light modulator that forms, on a light modulation region, a two-dimensional pattern for defining the image; and
one or a plurality of semiconductor laser devices that irradiate the light modulation region of the spatial light modulator with laser light;
wherein:
the spatial light modulator generates a bundle of a plurality of light beams, having a spatial intensity distribution of the two-dimensional pattern, from the laser light; and
the one or the plurality of semiconductor laser devices are all located such that a semiconductor layer-layer-stacking direction thereof is perpendicular to a minimum size direction of the light modulation region of the spatial light modulator.

17. The projector of claim 16, wherein the laser light emitted from the semiconductor laser device(s) is incident on the light modulation region of the spatial light modulator while enlarging a cross-section thereof perpendicular to an optical axis thereof.

18. The projector of claim 16, wherein:
the spatial light modulator includes a polarizer film on a side on which the plurality of light beams are output; and
a polarization transmission axis of the polarizer film is perpendicular to the minimum size direction of the light modulation region.
